(19) United States
(12) Patent Application Publication
(10) Pub. No.: US 2026/0255827 A1
(43) Pub. Date: Aug. 27, 2026

(54) DISPLAY DEVICE AND ELECTRONIC DEVICE INCLUDING THE SAME

(71) Applicant: Samsung Display Co., Ltd., Yongin-Si (KR)

(72) Inventors: Dong Hee SHIN, Yongin-si (KR); Yun Mi KIM, Yongin-si (KR); Hyeong Seok KIM, Yongin-si (KR); Do Yeong PARK, Yongin-si (KR)

(21) Appl. No.: 19/315,869

(22) Filed: Sep. 2, 2025

(30) Foreign Application Priority Data
Feb. 24, 2025 (KR) 10-2025-0023755

(51) Int. Cl. H10K 59/131; H10K 59/121

(52) U.S. Cl. CPC H10K 59/1315; H10K 59/1213; H10K 59/1216

(57) ABSTRACT

Provided a display device which comprises a substrate; a circuit layer; and an element layer. The circuit layer comprises light emitting pixel drivers arranged side by side with each other in a first direction and a second direction; data lines extending in the second direction; first auxiliary lines extending in the first direction; and second auxiliary lines extending in the second direction and disposed adjacent to the data lines. The light emitting pixel drivers comprise a first light emitting pixel driver and a second light emitting pixel driver that are adjacent in the second direction. Among the first auxiliary lines, two first auxiliary lines that are adjacent in the second direction intersect the first light emitting pixel driver or the second light emitting pixel driver and are located adjacent to a boundary between the first light emitting pixel driver and the second light emitting pixel driver.

### CROSS-REFERENCE TO RELATED APPLICATION

This application claims priority to Korean Patent Application No. 10-2025-0023755 filed on Feb. 24, 2025, in the Korean Intellectual Property Office, and all the benefits accruing therefrom under 35 U.S.C. 119, the contents of which in its entirety are incorporated herein by reference.

### BACKGROUND

### 1. Technical Field

The present disclosure relates to a display device and an electronic device including the same.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions.

The display device may be a flat panel display device such as a liquid crystal display device, a field emission display device and a light emitting display device. Examples of the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device displays an image using light emitting elements, each including a light emitting layer containing an organic light emitting material. As described above, the organic light emitting display device implements image display using a self-light emitting element, and thus may have relatively superior performance in power consumption, response speed, luminous efficiency, luminance, and wide viewing angle compared to other display devices.

In the display device, a display surface from which light is emitted may include a display area in which an image is displayed and a non-display area around the display area. Emission areas emitting light with respective luminances and colors may be arranged in the display area.

### SUMMARY

The display device may include light emitting pixel drivers that transmit a driving current to light emitting elements.

As the width of the light emitting pixel drivers decreases, the number of light emitting pixel drivers that may be located in the display area may increase, which may be advantageous for achieving high resolution of the display device.

In view of the foregoing, aspects of the present disclosure provide a display device and an electronic device including the same, which may be advantageous for achieving high resolution because the width of the light emitting pixel drivers may be reduced.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device comprises a substrate comprising a display area in which emission areas are arranged; a circuit layer located on the substrate; and an element layer located on the circuit layer. The circuit layer comprises light emitting pixel drivers arranged side by side with each other in a first direction and a second direction in the display area; data lines extending in the second direction and transmitting a data signal to the light emitting pixel drivers; first auxiliary lines extending in the first direction; and second auxiliary lines extending in the second direction and disposed adjacent to the data lines. The light emitting pixel drivers comprise a first light emitting pixel driver and a second light emitting pixel driver that are adjacent in the second direction. Among the first auxiliary lines, two first auxiliary lines that are adjacent in the second direction intersect the first light emitting pixel driver or the second light emitting pixel driver and are located adjacent to a boundary between the first light emitting pixel driver and the second light emitting pixel driver.

The second auxiliary lines comprise one second auxiliary line intersecting the first light emitting pixel driver and the second light emitting pixel driver. The one second auxiliary line comprises a first protrusion that overlaps the two first auxiliary lines.

The first protrusion further overlaps a second protrusion extending from one first auxiliary line of the two first auxiliary lines.

The light emitting pixel drivers further comprise a third light emitting pixel driver and a fourth light emitting pixel driver, respectively, adjacent to the first light emitting pixel driver and the second light emitting pixel driver in the first direction. The two first auxiliary lines intersect the third light emitting pixel driver or the fourth light emitting pixel driver and are located adjacent to a boundary between the third light emitting pixel driver and the fourth light emitting pixel driver. The second auxiliary lines further comprise another second auxiliary line intersecting the third light emitting pixel driver and the fourth light emitting pixel driver. The another second auxiliary line comprises a third protrusion that overlaps the two first auxiliary lines.

The third protrusion further overlaps a fourth protrusion extending from another first auxiliary line of the two first auxiliary lines.

The second protrusion faces the another first auxiliary line in the second direction. The fourth protrusion faces the one first auxiliary line in the second direction.

The first protrusion and the third protrusion are arranged with the same width in the second direction and are arranged side by side in the first direction.

The display device further comprises a display driving circuit supplying a data signal to the data lines. The substrate further comprises a non-display area located around the display area. The circuit layer further comprises data supply lines located in the non-display area and electrically connected between the data lines and the display driving circuit. A bypass area on one side of the display area comprises a bypass middle area, a first bypass side area that is parallel to the bypass middle area in the first direction and in contact with the non-display area, and a second bypass side area that is located between the bypass middle area and the first bypass side area. The data supply lines extend to the bypass middle area and the second bypass side area. The data lines comprise a first data line located in the first bypass side area, and a second data line located in the second bypass side area. The first auxiliary lines comprise a first bypass auxiliary line electrically connected to the first data line. The second auxiliary lines comprise a second bypass auxiliary line that is electrically connected to the first bypass auxiliary line and is adjacent to the second data line. Among the data supply lines, a first data supply line transmitting a data signal of the first data line is electrically connected to the first data line through the first bypass auxiliary line and the second bypass auxiliary line. Among the data supply lines, a second data supply line transmitting a data signal of the second data line is electrically connected directly to the second data line.

The element layer comprises light emitting elements arranged in the emission areas. Each of the light emitting pixel drivers comprises a first transistor generating the driving current; a second transistor electrically connected between one of the data lines and a gate electrode of the first transistor; a third transistor electrically connected between a reference voltage line transmitting a reference voltage and the gate electrode of the first transistor; a fourth transistor electrically connected between an initialization voltage line transmitting an initialization voltage and one of the light emitting elements; a fifth transistor electrically connected between a first power line transmitting a first power and a first electrode portion of the first transistor; a sixth transistor electrically connected between the one light emitting element and a second electrode portion of the first transistor; a first capacitor electrically connected between the gate electrode of the first transistor and the second electrode portion of the first transistor; and a second capacitor electrically connected between the first power line transmitting the first power and the second electrode portion of the first transistor. A gate electrode of the second transistor is electrically connected to a scan write line transmitting a scan write signal. A gate electrode of the third transistor is electrically connected to a reset control line transmitting a reset control signal. A gate electrode of the fourth transistor is electrically connected to an initialization control line transmitting an initialization control signal. A gate electrode of the fifth transistor is electrically connected to a first emission control line transmitting a first emission control signal. A gate electrode of the sixth transistor is electrically connected to a second emission control line transmitting a second emission control signal.

The circuit layer comprises a first semiconductor layer located on the substrate; a first interlayer insulating layer located on the first semiconductor layer; and a second semiconductor layer located on the first interlayer insulating layer and containing an oxide semiconductor material. A channel portion, the first electrode portion and the second electrode portion of the first transistor are located in the second semiconductor layer. A channel portion, a first electrode portion and a second electrode portion of the sixth transistor are located in the first semiconductor layer.

The light emitting pixel drivers further comprise a fifth light emitting pixel driver adjacent to the second light emitting pixel driver in the second direction. Each of the reference voltage line, the reset control line, the first emission control line, the second emission control line, the initialization control line, and the initialization voltage line extends in the first direction. Some of the reference voltage line, the reset control line, the first emission control line, the second emission control line, the initialization control line, and the initialization voltage line intersect the second light emitting pixel driver, and some others intersect the fifth light emitting pixel driver.

The third transistor of each of the second light emitting pixel driver and the fifth light emitting pixel driver is electrically connected to the reset control line and the reference voltage line intersecting the second light emitting pixel driver. The fourth transistor of each of the second light emitting pixel driver and the fifth light emitting pixel driver is electrically connected to the initialization voltage line and the initialization control line intersecting the fifth light emitting pixel driver. The fifth transistor of each of the second light emitting pixel driver and the fifth light emitting pixel driver is electrically connected to the first emission control line intersecting the second light emitting pixel driver. The sixth transistor of each of the second light emitting pixel driver and the fifth light emitting pixel driver is electrically connected to the second emission control line intersecting the fifth light emitting pixel driver.

The third transistor and the fifth transistor of the fifth light emitting pixel driver are respectively adjacent to the third transistor and the fifth transistor of the second light emitting pixel driver in the first direction. The fourth transistor and the sixth transistor of the second light emitting pixel driver are respectively adjacent to the fourth transistor and the sixth transistor of the fifth light emitting pixel driver in the first direction.

According to an aspect of the present disclosure, there is provided an electronic device comprises a display device displaying an image; a memory storing an application; a processor executing the application and transmitting an image data signal and an input control signal to the display device; and a power module transmitting power to the display device. The display device comprises a substrate comprising a display area in which emission areas are arranged; a circuit layer located on the substrate; and an element layer located on the circuit layer. The circuit layer comprises light emitting pixel drivers arranged side by side with each other in a first direction and a second direction in the display area; data lines extending in the second direction and transmitting a data signal to the light emitting pixel drivers; first auxiliary lines extending in the first direction; and second auxiliary lines extending in the second direction and adjacent to the data lines. The light emitting pixel drivers comprise a first light emitting pixel driver and a second light emitting pixel driver that are adjacent in the second direction; and a third light emitting pixel driver and a fourth light emitting pixel driver, respectively, adjacent to the first light emitting pixel driver and the second light emitting pixel driver in the first direction. Among the first auxiliary lines, two first auxiliary lines that are adjacent in the second direction intersect the first light emitting pixel driver or the second light emitting pixel driver and are located adjacent to a boundary between the first light emitting pixel driver and the second light emitting pixel driver. The two first auxiliary lines intersect the third light emitting pixel driver or the fourth light emitting pixel driver and are located adjacent to a boundary between the third light emitting pixel driver and the fourth light emitting pixel driver.

The second auxiliary lines comprise one second auxiliary line intersecting the first light emitting pixel driver and the second light emitting pixel driver; and another second auxiliary line intersecting the third light emitting pixel driver and the fourth light emitting pixel driver. The one second auxiliary line comprises a first protrusion overlapping the two first auxiliary lines. The first protrusion further overlaps a second protrusion extending from one first auxiliary line of the two first auxiliary lines. The another second auxiliary line comprises a third protrusion overlapping the two first auxiliary lines. The third protrusion further overlaps a fourth protrusion extending from the other first auxiliary line of the two first auxiliary lines.

The second protrusion faces the other first auxiliary line of the two first auxiliary lines in the second direction. The fourth protrusion faces the one first auxiliary line in the second direction. The first protrusion and the third protrusion are arranged with the same width in the second direction and are arranged side by side in the first direction.

The display device further comprises a display driving circuit supplying a data signal to the data lines. The substrate further comprises a non-display area located around the display area. The circuit layer further comprises data supply lines located in the non-display area and electrically connected between the data lines and the display driving circuit. A bypass area on one side of the display area comprises a bypass middle area, a first bypass side area that extends parallel to the bypass middle area in the first direction and in contact with the non-display area, and a second bypass side area that is located between the bypass middle area and the first bypass side area. The data supply lines extend to the bypass middle area and the second bypass side area. The data lines comprise a first data line located in the first bypass side area, and a second data line located in the second bypass side area. The first auxiliary lines comprise a first bypass auxiliary line electrically connected to the first data line. The second auxiliary lines comprise a second bypass auxiliary line that is electrically connected to the first bypass auxiliary line and is adjacent to the second data line. Among the data supply lines, a first data supply line transmitting a data signal of the first data line is electrically connected to the first data line through the first bypass auxiliary line and the second bypass auxiliary line. Among the data supply lines, a second data supply line transmitting a data signal of the second data line is electrically connected directly to the second data line.

The element layer comprises light emitting elements arranged in the emission areas. Each of the light emitting pixel drivers comprises a first transistor generating the driving current; a second transistor electrically connected between one of the data lines and a gate electrode of the first transistor; a third transistor electrically connected between a reference voltage line transmitting a reference voltage and the gate electrode of the first transistor; a fourth transistor electrically connected between an initialization voltage line transmitting an initialization voltage and one of the light emitting elements; a fifth transistor electrically connected between a first power line transmitting a first power and a first electrode portion of the first transistor; a sixth transistor electrically connected between the one light emitting element and a second electrode portion of the first transistor; a first capacitor electrically connected between the gate electrode of the first transistor and the second electrode portion of the first transistor; and a second capacitor electrically connected between the first power line transmitting the first power and the second electrode portion of the first transistor. A gate electrode of the second transistor is electrically connected to a scan write line transmitting a scan write signal. A gate electrode of the third transistor is electrically connected to a reset control line transmitting a reset control signal. A gate electrode of the fourth transistor is electrically connected to an initialization control line transmitting an initialization control signal. A gate electrode of the fifth transistor is electrically connected to a first emission control line transmitting a first emission control signal. A gate electrode of the sixth transistor is electrically connected to a second emission control line transmitting a second emission control signal. The light emitting pixel drivers further comprise a fifth light emitting pixel driver adjacent to the second light emitting pixel driver in the second direction. Each of the reference voltage line, the reset control line, the first emission control line, the second emission control line, the initialization control line, and the initialization voltage line extends in the first direction. Some of the reference voltage line, the reset control line, the first emission control line, the second emission control line, the initialization control line, and the initialization voltage line intersect the second light emitting pixel driver, and some others intersect the fifth light emitting pixel driver.

The third transistor and the fifth transistor of the fifth light emitting pixel driver are respectively adjacent to the third transistor and the fifth transistor of the second light emitting pixel driver in the first direction. The fourth transistor and the sixth transistor of the second light emitting pixel driver are respectively adjacent to the fourth transistor and the sixth transistor of the fifth light emitting pixel driver in the first direction.

The circuit layer comprises a first semiconductor layer located on the substrate; a first interlayer insulating layer located on the first semiconductor layer; and a second semiconductor layer located on the first interlayer insulating layer and containing an oxide semiconductor material. Each of the first transistor, the second transistor, the third transistor, the fourth transistor, the fifth transistor, and the sixth transistor comprises a gate electrode, a channel portion overlapping the gate electrode, a first electrode portion connected to one side of the channel portion, and a second electrode portion connected to the other side of the channel portion. The channel portion, the first electrode portion and the second electrode portion of each of the first transistor, the second transistor, the third transistor and the fourth transistor are located in the second semiconductor layer. The channel portion, the first electrode portion and the second electrode portion of each of the fifth transistor and the sixth transistor are located in the first semiconductor layer.

A circuit layer of a display device according to one embodiment may include light emitting pixel drivers arranged side by side with each other in a first direction and a second direction in a display area, data lines extending in the second direction and transmitting a data signal to the light emitting pixel drivers, first auxiliary lines extending in the first direction, and second auxiliary lines extending in the second direction and adjacent to the data lines.

According to embodiments, the light emitting pixel drivers may include a first light emitting pixel driver and a second light emitting pixel driver that are adjacent in the second direction.

Among the first auxiliary lines, two first auxiliary lines that are adjacent in the second direction may be located adjacent to a boundary between the first light emitting pixel driver and the second light emitting pixel driver.

That is, since each of the first auxiliary lines does not intersect one side of the light emitting pixel drivers, the width of the area in which the first auxiliary lines are located may be reduced.

Accordingly, the width of the light emitting pixel drivers may be reduced, which may be advantageous for achieving high resolution of the display device.

According to one embodiment, the second auxiliary lines may comprise one second auxiliary line intersecting the first light emitting pixel driver and the second light emitting pixel driver. The one second auxiliary line may comprise a first protrusion that overlaps the two first auxiliary lines.

The first protrusion may further overlap a second protrusion extending from one first auxiliary line of the two first auxiliary lines.

The second protrusion may face another first auxiliary line of the two first auxiliary lines in the second direction.

That is, since the first protrusion overlaps only the second protrusion extending from one first auxiliary line, rather than overlapping two protrusions extending from each of the two first auxiliary lines, the width of the area in which the first protrusion and the second protrusion are located may be reduced.

Accordingly, the width of the light emitting pixel drivers may be reduced, which may be more advantageous for achieving high resolution of the display device.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view showing an electronic device according to one embodiment;

FIG. 2 is an exploded perspective view of the electronic device shown in FIG. 1;

FIG. 3 is a plan view illustrating the display device of FIG. 2;

FIG. 4 is a cross-sectional view taken along line A-A′ of FIG. 3;

FIG. 5 is a schematic diagram showing part B of FIG. 3;

FIG. 6 is a block diagram showing the display device of FIG. 2;

FIG. 7 is an equivalent circuit diagram showing the light emitting pixel driver of FIG. 6 according to one embodiment;

FIG. 8 is a cross-sectional view illustrating the first transistor, the second transistor, the sixth transistor, the first capacitor, the second capacitor, and the light emitting element of FIG. 7;

FIG. 9 is a plan view illustrating the substrate of FIG. 4 according to one embodiment;

FIG. 10 is a schematic diagram showing part C of FIG. 9;

FIG. 11 is a schematic diagram showing part D of FIG. 9;

FIG. 12 is a plan view illustrating part E of FIG. 10;

FIG. 13 is a plan view showing part F of FIG. 11;

FIG. 14 is a cross-sectional view taken along line G-G′ of FIG. 12;

FIG. 15 is a schematic diagram illustrating the arrangement of the lines of FIG. 7 according to one embodiment;

FIG. 16 is a block diagram of an electronic device according to one embodiment; and

FIG. 17 is schematic views of electronic devices according to various embodiments.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

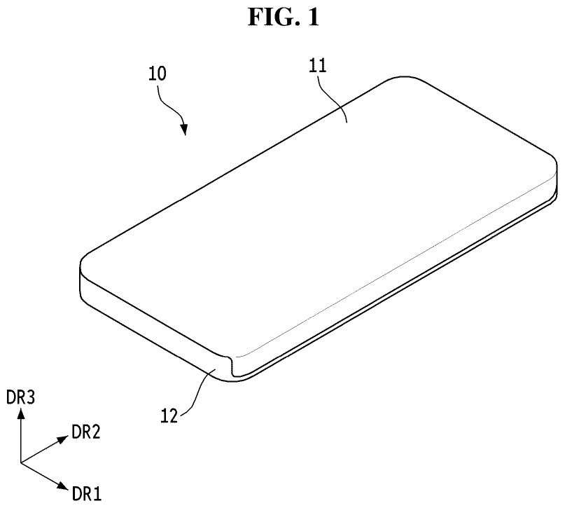

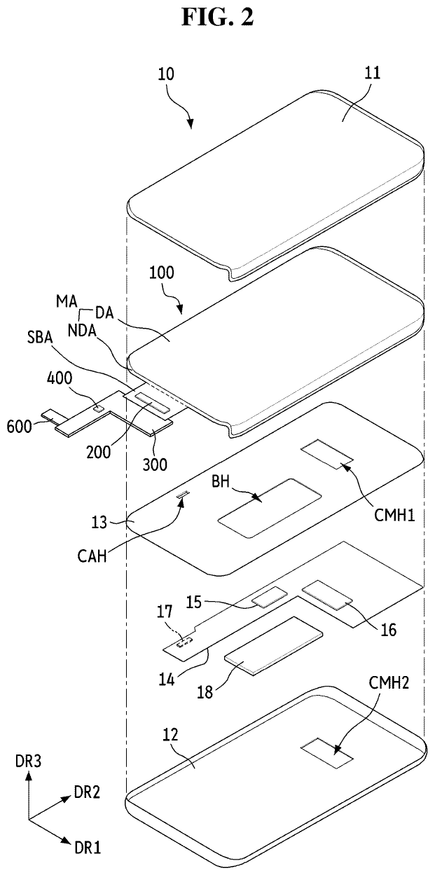

FIG. 1 is a perspective view showing an electronic device according to one embodiment. FIG. 2 is an exploded perspective view of the electronic device shown in FIG. 1.

Referring to FIG. 1, an electronic device 10 according to one embodiment is a device having a function of displaying an image in a display area. The electronic device 10 may be a portable electronic device. For example, the electronic device 10 may be a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

However, the electronic device 10 according to one embodiment is not limited to a portable electronic device, and may be a large-sized device such as a television, a laptop computer, a monitor, a billboard, and an Internet-of-Things (IoT) device.

The electronic device 10 according to one embodiment may include a cover window 11 and a lower cover 12, which are provided as a housing to protect a display device 100 (see FIG. 2).

Referring to FIG. 2, the electronic device 10 may further include the display device 100, a bracket 13, and a main circuit board 14 which are accommodated between the cover window 11 and the lower cover 12.

The display device 100 may include a main region MA including a display area DA where an image is displayed and a non-display area NDA around the display area DA, and a sub-region SBA protruding from one side of the main region MA.

The display device 100 may further include a display driving circuit 200 located in the sub-region SBA, a display circuit board 300 bonded to one side of the sub-region SBA, a touch driving circuit 400 mounted on the display circuit board 300, and a cable 600 extending from one side of the display circuit board 300.

In the present specification, a first direction DR1 may be a direction parallel to a short side of the electronic device 10 in a plan view, that is, a horizontal direction of the electronic device 10. A second direction DR2 may be a direction parallel to a long side of the electronic device 10 in a plan view, that is, a vertical direction of the electronic device 10. A third direction DR3 may be a thickness direction of the electronic device 10.

The electronic device 10 may have a shape close to a rectangular shape in a plan view. For example, the electronic device 10 may have a rectangular shape, in a plan view, having a short side in the first direction DR1 and a long side in the second direction DR2. A corner where the short side in the first direction DR1 and the long side in the second direction DR2 meet may be right-angled or rounded with a selected curvature. The planar shape of the electronic device 10 is not limited to the rectangular shape and may be formed in another polygonal shape, a circular shape or an elliptical shape.

The cover window 11 may be located on the display device 100 to cover the top surface of the display device 100. The cover window 11 may serve to protect the top surface of the display device 100.

The cover window 11 may include a light transmitting portion that is transparent and a light blocking portion that is opaque.

The light transmitting portion may overlap the display area DA of the display device 100 in the third direction DR3, and the light blocking portion may overlap the non-display area NDA of the display device 100 in the third direction DR3.

The cover window 11 may include a top surface portion forming the top surface of the electronic device 10, a left surface portion forming the left side surface of the electronic device 10, and a right surface portion forming the right side surface of the electronic device 10. The left surface portion of the cover window 11 may extend from the left side of the top surface portion and the right surface portion thereof may extend from the right side of the top surface portion.

Each of the top, left, and right surface portions of the cover window 11 may include the light transmitting portion and the light blocking portion.

The light transmitting portion of the cover window 11 may be located on most of each of the top, left, and right surface portions of the cover window 11.

The light blocking portion of the cover window 11 may be located at the upper edge and lower edge of the top surface portion of the cover window 11, the upper edge, left edge, and lower edge of the left surface portion of the cover window 11, and the upper edge, right edge, and lower edge of the right surface portion of the cover window 11.

The display device 100 may be located below the cover window 11.

That is, the cover window 11 may be located on the display device 100.

The display device 100 may include a top surface portion facing a bottom surface portion of the cover window 11, a left surface portion facing the left surface portion of the cover window 11, and a right surface portion facing the right surface portion of the cover window 11. The left surface portion of the display device 100 may extend from the left side of the top surface portion, and the right surface portion of the display device 100 may extend from the right side of the top surface portion.

The display device 100 may include the main region MA serving as a display surface and the sub-region SBA protruding from at least a part of one side of the main region MA.

The main region MA may include the display area DA displaying an image and the non-display area NDA that is a peripheral area of the display area DA.

The display area DA may be located in most of the main region MA. The display area DA may be located at the center of the main region MA.

In other words, each of the top, left, and right surface portions of the display device 100 may include the display area DA and the non-display area NDA.

The display area DA may be located on most of each of the top, left, and right surface portions of the display device 100.

The non-display area NDA may be located outside the display area DA. The non-display area NDA may be an edge area of the main region MA.

The non-display area NDA may be located at the upper edge and lower edge of the top surface portion of the display device 100, the upper edge, left edge, and lower edge of the left surface portion of the display device 100, and the upper edge, right edge, and lower edge of the right surface portion of the display device 100.

The sub-region SBA may protrude from one side of the main region MA in the second direction DR2.

The length of the sub-region SBA in the first direction DR1 may be less than or equal to the length of the main region MA in the first direction DR1. The length of the sub-region SBA in the second direction DR2 may be less than the length of the main region MA in the second direction DR2, but is not limited thereto.

Since a part of the sub-region SBA is bendable, another part of the sub-region SBA may overlap the main region MA in the third direction DR3 when the sub-region SBA is bent.

The display driving circuit 200 may be mounted on the sub-region SBA, and the display circuit board 300 may be attached to the sub-region SBA.

One end of the display circuit board 300 may be attached to pads located at the lower edge of the sub-region SBA of the display device 100 by using an anisotropic conductive film.

The display circuit board 300 may be a flexible printed circuit board (FPCB) which is bendable, a rigid printed circuit board (PCB) which maintains a flat shape, or a composite printed circuit board having both of the rigid printed circuit board and the flexible printed circuit board.

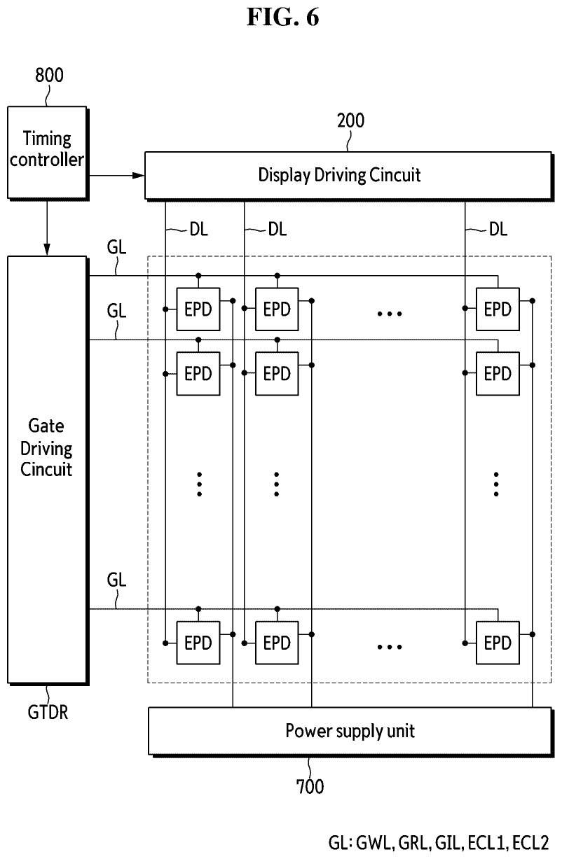

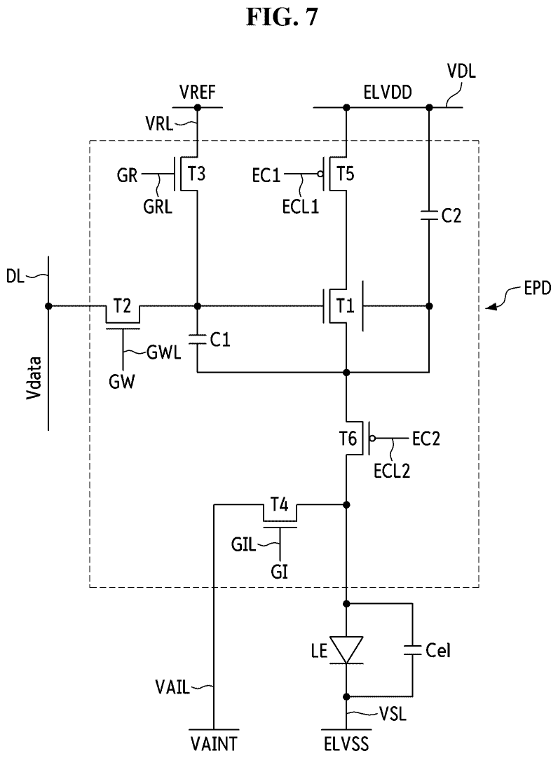

In response to control signals, power and voltages supplied through the display circuit board 300, the display driving circuit 200 may transmit a data signal Vdata (see FIG. 7) of each of light emitting pixel drivers EPD (see FIG. 6) of the display area DA to data lines DL (see FIG. 6).

The display driving circuit 200 may be provided as an integrated circuit (IC) and mounted on the sub-region SBA of the display device 100 by a chip on glass (COG) method, a chip on plastic (COP) method, or an ultrasonic method. However, this is only an example and one embodiment is not limited thereto. For example, the display driving circuit 200 may be mounted on the display circuit board 300.

According to one embodiment, the touch driving circuit 400 may be further mounted on the sub-region SBA of the display device 100.

Alternatively, as shown in FIG. 2, the touch driving circuit 400 may be mounted on the display circuit board 300.

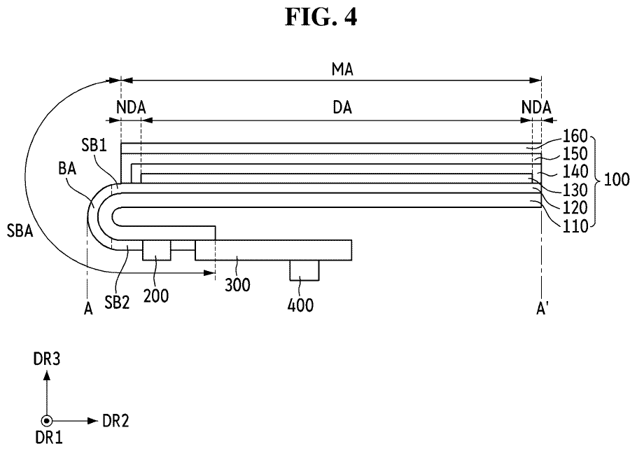

The touch driving circuit 400 may be electrically connected to a touch sensor layer 150 (see FIG. 4) of the display device 100.

As shown in FIG. 2, the bracket 13 may be located under the display device 100.

The bracket 13 may include plastic or metal. The bracket 13 may include a first camera hole CMH1 into which a camera device 16 is inserted, a battery hole BH into which a battery 18 is located, and a cable hole CAH through which the cable 600 connected to the display circuit board 300 passes.

The main circuit board 14 and the battery 18 may be located under the bracket 13.

The main circuit board 14 may be a printed circuit board or a flexible printed circuit board.

The main circuit board 14 may include a main processor 15, the camera device 16, and a main connector 17. The main processor 15 may be formed as an integrated circuit.

The camera device 16 may be located on both the top surface and the bottom surface of the main circuit board 14, the main processor 15 may be located on the top surface of the main circuit board 14, and the main connector 17 may be located on the bottom surface of the main circuit board 14.

The main processor 15 may control all functions of the electronic device 10.

For example, the main processor 15 may output digital video data to the display driving circuit 200 through the display circuit board 300 such that the display device 100 displays an image. In addition, the main processor 15 may receive touch data including user's touch coordinates from the touch driving circuit 400, determine whether or not the user has touched or approached, and then perform an operation corresponding to the user's touch input or approach input. For example, the main processor 15 may perform an operation or execute an application indicated by an icon touched by the user.

The main processor 15 may be an application processor including an integrated circuit, a central processing unit, or a system chip.

The camera device 16 may process an image frame of a still image or video obtained by an image sensor in a camera mode and output it to the main processor 15.

The cable 600 may be connected to the main connector 17 through the cable hole CAH in the bracket 13. Thus, the main circuit board 14 may be electrically connected to the display circuit board 300.

The battery 18 may be located so as not to overlap the main circuit board 14 in the third direction DR3. The battery 18 may be disposed in the battery hole BH of the bracket 13 in the third direction DR3.

In addition, the main circuit board 14 may be further equipped with a mobile communication module capable of transmitting and receiving radio signals with at least one of a base station, an external terminal, or a server in a mobile communication network. The radio signal may include various types of data according to transmission and reception of a voice signal, a video call signal, or a text/multimedia message.

The lower cover 12 may be located below the main circuit board 14 and the battery 18. The lower cover 12 may be fixed to the bracket 13. The lower cover 12 may form the upper side surface, lower side surface, and bottom surface of the electronic device 10. The lower cover 12 may include plastic, metal, or both plastic and metal.

The lower cover 12 may include a second camera hole CMH2 through which the bottom surface of the camera device 16 is exposed. The position of the camera device 16 and the positions of the first camera hole CMH1 and the second camera hole CMH2 corresponding to the camera device 16 are not limited by the illustration in FIG. 2.

Next, the display device 100 according to one embodiment will be described.

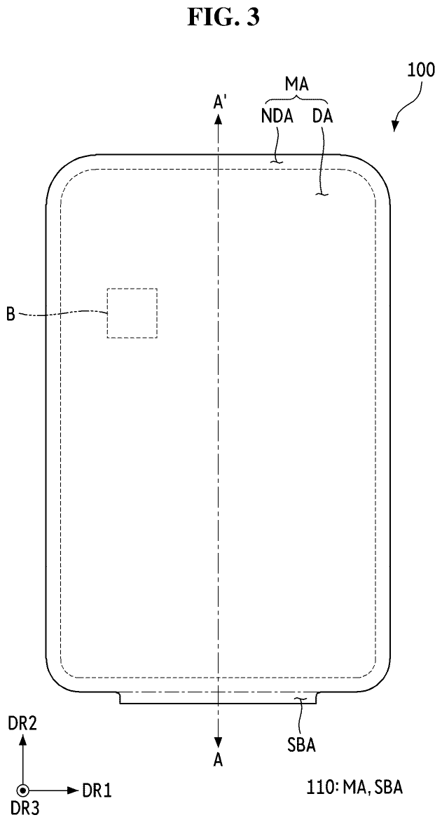

FIG. 3 is a plan view illustrating the display device of FIG. 2. FIG. 4 is a cross-sectional view taken along line A-A′ of FIG. 3.

Referring to FIGS. 3 and 4, the display device 100 according to one embodiment, which is a device for displaying a moving image or a still image, may be used as a display screen of various devices such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 100 may be a light emitting display device such as an organic light emitting display using an organic light emitting diode, a quantum dot light emitting display including a quantum dot light emitting layer, an inorganic light emitting display including an inorganic semiconductor, and a micro light emitting display using a micro or nano light emitting diode (LED). In the following description, it is assumed that the display device 100 is an organic light emitting display device. However, the present disclosure is not limited thereto and may be applied to a display device including an organic insulating material, an organic light emitting material, and a metal material.

The display device 100 may have a flat shape, but the configuration of the display device 100 is not limited thereto. For example, the display device 100 may include a curved portion formed at left and right ends and having a constant curvature or a varying curvature. In addition, the display device 100 may be formed to be flexible so that it can be curved, bent, folded, or rolled.

Referring to FIG. 3, at least one surface of the display device 100 includes the main region MA a portion from which light for displaying an image is emitted.

The display area DA may, in a plan view, be formed in a rectangular shape having short sides in a first direction DR1 and long sides in a second direction DR2 crossing the first direction DR1. The corner where the short side in the first direction DR1 and the long side in the second direction DR2 meet may be rounded to have a selected curvature or may be right-angled. The planar shape of the display area DA is not limited to the rectangular shape and may be formed in another polygonal shape, a circular shape or an elliptical shape.

The display area DA may be located in most of the main region MA. The display area DA may be located at the center of the main region MA.

Referring to FIG. 4, the display device 100 may further include the sub-region SBA protruding in the second direction DR2 from at least a part of one side of the main region MA.

Since a part of the sub-region SBA is bendable, another part of the sub-region SBA may be located on the rear surface of the display device 100 when the part of the sub-region SBA is bent.

According to one embodiment, the display device 100 includes a substrate 110, a circuit layer 120 located on the substrate 110, and an element layer 130 located on the circuit layer 120.

The display device 100 may further include an encapsulation layer 140 located on the element layer 130, and the touch sensor layer 150 located on the encapsulation layer 140.

The display device 100 may further include a polarization layer 160 located on the touch sensor layer 150 in order to reduce reflection of external light.

The substrate 110 may include the main region MA corresponding to the display surface and the sub-region SBA protruding in the second direction DR2 from at least a part of one side of the main region MA.

The main region MA of the substrate 110 may include the display area DA from which light is emitted and the non-display area NDA located around the display area DA.

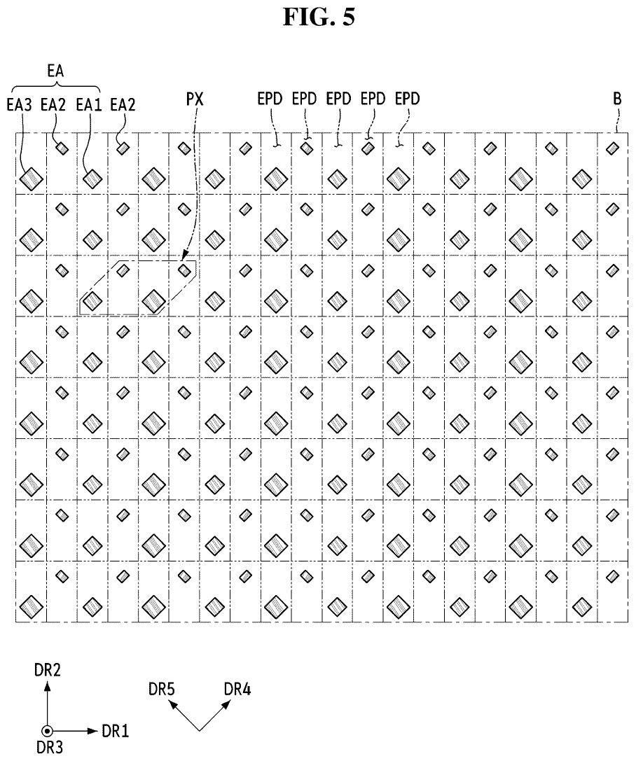

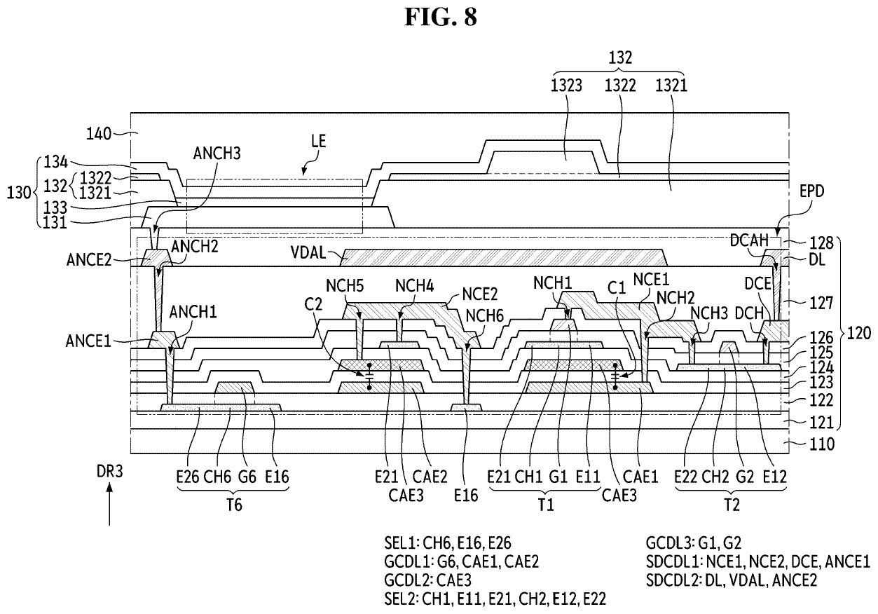

According to one embodiment, the element layer 130 may include light emitting elements LE (see FIGS. 7 and 8) respectively located in the emission areas EA (see FIG. 5).

The circuit layer 120 may include the light emitting pixel drivers EPD (see FIG. 5) electrically connected to the light emitting elements LE and the data lines DL (see FIGS. 6 and 7) that transmit the data signal Vdata (see FIG. 7) of the light emitting pixel drivers EPD (see FIG. 5).

The encapsulation layer 140 may cover the element layer 130. The encapsulation layer 140 may include a structure in which two or more inorganic layers and at least one organic layer are alternately stacked.

The touch sensor layer 150 may be located on the encapsulation layer 140 in an area correspond to the main region MA. The touch sensor layer 150 may include touch electrodes for sensing a touch of a person or an object.

The polarization layer 160 blocks external light reflected from the touch sensor layer 150, the encapsulation layer 140, the element layer 130, and the circuit layer 120, and the interfaces thereof, to prevent the deterioration of visibility of an image due to external light reflection.

Meanwhile, as a part of the sub-region SBA is bendable, the display driving circuit 200 mounted in the sub-region SBA, and the display circuit board 300 connected to one side of the sub-region SBA may be located under the substrate 110.

The display driving circuit 200 may be electrically connected to the data lines DL (see FIGS. 6 and 7) of the circuit layer 120. The display driving circuit 200 may transmit the data signals Vdata (see FIG. 7) of the light emitting pixel drivers EPD (see FIG. 5) through the data lines DL in response to control signals and power voltages supplied from the display circuit board 300.

The display driving circuit 200 may be provided as an integrated circuit (IC) and mounted on the sub-region SBA of the display device 100 by a chip on glass (COG) method, a chip on plastic (COP) method, or an ultrasonic method. However, this is only an example, and one embodiment is not limited thereto. For example, the display driving circuit 200 may be mounted on the display circuit board 300.

One end of the display circuit board 300 may be attached onto pads located on one edge of the sub-region SBA of the display device 100 by using an anisotropic conductive film.

The display circuit board 300 may be a flexible printed circuit board (FPCB) which is bendable, a rigid printed circuit board (PCB) which maintains a flat shape, or a composite printed circuit board having both of the rigid printed circuit board and the flexible printed circuit board.

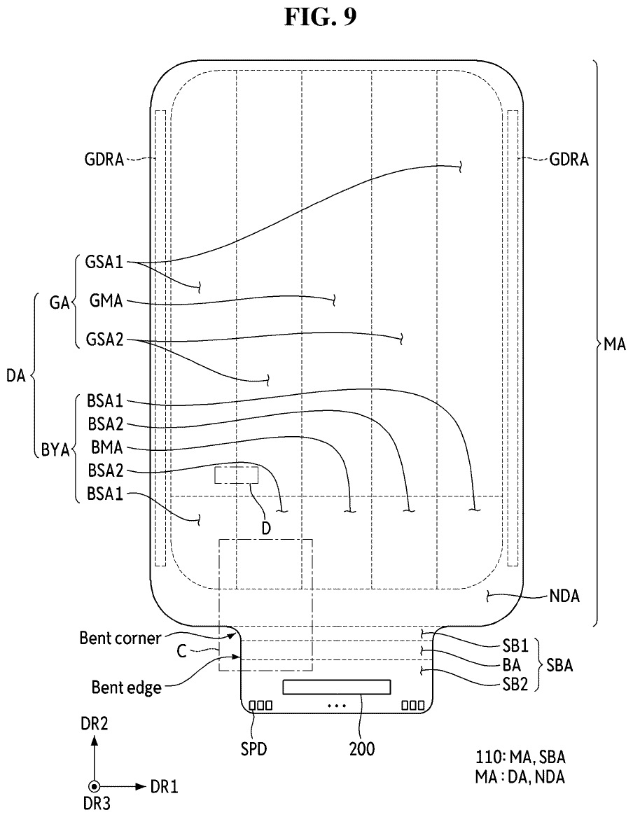

The display circuit board 300 may be connected to signal pads SPD (see FIG. 9) located on one side of the sub-region SBA.

The touch driving circuit 400 may be mounted on the display circuit board 300.

The touch driving circuit 400 may be electrically connected to the touch sensor layer 150 of the display device 100.

The touch driving circuit 400 may apply a touch driving signal to driving lines of the touch sensor layer 150 and receive a touch sensing signal from sensing lines. Further, the touch driving circuit 400 may detect charge variation amounts of capacitances through the touch sensing signal, thereby determining whether a user has touched or approached.

The user's touch means that an object such as a pen or a user's finger is in direct contact with the top surface of the cover window located on the touch sensor layer. The user's approach means that the object such as the pen or the user's finger hovers over the top surface of the cover window.

The touch driving circuit 400 may output touch data including the user's touch coordinates to the main processor 15 (see FIG. 2).

FIG. 5 is a schematic diagram showing part B of FIG. 3.

As shown in FIG. 5, the display area DA may include the emission areas EA from which light is emitted and a non-emission area that is disposed between the emission areas EA and from which light is not emitted.

Each of the emission areas EA may be a unit area that emits light with a wavelength band corresponding to one color of two or more different colors with a luminance corresponding to an image signal.

Each of the emission areas EA may be arranged in a quadrilateral shape.

However, this is only an example and the planar shape of the emission areas EA according to one embodiment is not limited to that illustrated in FIG. 5. That is, the emission areas EA may have a planar shape of a polygon such as a rectangle, a square, a hexagon, and an octagon other than a rhombus, a circle, or an ellipse.

The emission areas EA may include first emission areas EA1 that emit light with a first wavelength band, second emission areas EA2 that emit light with a second wavelength band lower than the first wavelength band, and third emission areas EA3 that emit light with a third wavelength band lower than the second wavelength band.

For example, the first wavelength band may be from about 600 nm to about 750 nm and may correspond to a red color. The second wavelength band may be from about 480 nm to about 560 nm and may correspond to a green color. The third wavelength band may be from about 370 nm to about 460 nm and may correspond to a blue color.

However, this is only an example and the first wavelength band, the second wavelength band, and the third wavelength band according to one embodiment are not limited thereto.

Since the emission areas EA include the first emission area EA1, the second emission area EA2, and the third emission area EA3, each of unit pixels PX may include a combination of one or more first emission areas EA1, one or more second emission areas EA2, and one or more third emission areas EA3 adjacent to each other among the emission areas EA.

Each of the unit pixels PX may be a unit for displaying various colors including white. That is, lights of various colors displayed by the unit pixels PX may be implemented as a mixture of lights emitted from two or more emission areas EA included in each unit pixel PX.

The third emission area EA3 may have a width greater than that of the first emission area EA1, and the first emission area EA1 may have a width greater than that of the second emission area EA2. However, this is merely an example, and the width of each of the emission areas EA is not limited to that illustrated in FIG. 5.

The first emission areas EA1 and the third emission areas EA3 may be alternately arranged in the first direction DR1.

The second emission areas EA2 may be arranged side by side in the second direction DR2.

Each of the second emission areas EA2 may be adjacent to the first emission area EA1 or the third emission area EA3 in diagonal directions DR4 and DR5 intersecting the first direction DR1 and the second direction DR2.

In this case, each of the unit pixels PX may include one first emission area EA1 and one third emission area EA3 adjacent to each other in the first direction DR1, and two second emission areas EA2 adjacent thereto in the diagonal directions DR4 and DR5. However, this is only an example, and the arrangement pattern of the emission areas EA and the components of the unit pixel PX according to one embodiment are not limited to the above description.

According to one embodiment, the circuit layer 120 (see FIG. 4) may include the light emitting pixel drivers EPD arranged in the first direction DR1 and the second direction DR2 in the display area DA.

The light emitting pixel drivers EPD may be respectively electrically connected to the light emitting elements LE (see FIGS. 7 and 8) of the element layer 130 (see FIG. 4). The light emitting elements LE may be located in the emission areas EA, respectively.

FIG. 6 is a block diagram showing the display device of FIG. 2.

Referring to FIG. 6, the circuit layer 120 of the display device 100 according to one embodiment may include the light emitting pixel drivers EPD electrically connected to the light emitting elements LE (see FIG. 7) arranged in the emission areas EA (see FIG. 5), and the data lines DL that transmit the data signals Vdata (see FIG. 7) to the light emitting pixel drivers EPD.

The circuit layer 120 may further include one or more gate lines GL that transmit one or more gate signals to the light emitting pixel drivers EPD.

According to one embodiment, the display device 100 may further include the display driving circuit 200 that outputs the data signals Vdata (see FIG. 7) of the light emitting pixel drivers EPD to the data lines DL in order to control the luminance of each of the light emitting elements LE (see FIG. 7).

According to one embodiment, the display device 100 may further include a gate driving circuit GTDR that outputs gate signals to the gate lines GL, a power supply unit 700 that supplies power and voltages to the light emitting pixel drivers EPD, and a timing controller 800 that controls the driving timing of each of the display driving circuit 200 and the gate driving circuit GTDR.

The timing controller 800 receives an image signal supplied from the outside of the display device 100.

The timing controller 800 may output image data DATA and a data control signal DCS to the display driving circuit 200.

The timing controller 800 may generate a scan control signal SCS for controlling the operation timing of the gate driving circuit GTDR.

The display driving circuit 200 may convert the image data DATA into analog data voltages and output them to the data lines DL.

The gate driving circuit GTDR may generate gate signals in response to the scan control signal SCS and sequentially output the gate signals to gate lines GL.

The gate lines GL may include a scan write line GWL that transmits a scan write signal GW (see FIG. 7), a reset control line GRL that transmits a reset control signal GR (see FIG. 7), an initialization control line GIL that transmits an initialization control signal GI (see FIG. 7), a first emission control line ECL1 that transmits a first emission control signal EC1 (see FIG. 7), and a second emission control line ECL2 that transmits a second emission control signal EC2 (see FIG. 7).

The gate signals may have pulses that swing between a first gate level voltage and a second gate level voltage.

The power supply unit 700 may supply various power and voltages necessary for driving the light emitting pixel drivers EPD.

For example, the power supply unit 700 may supply a first power ELVDD (see FIG. 7) and a second power ELVSS (see FIG. 7) for generating a driving signal transmitted to the light emitting elements LE, a reference voltage VREF (see FIG. 7) and an initialization voltage VINT (see FIG. 7) for initializing the light emitting elements LE (see FIG. 7).

FIG. 7 is an equivalent circuit diagram showing the light emitting pixel driver of FIG. 6 according to one embodiment.

Referring to FIG. 7, the circuit layer 120 (see FIG. 4) may include a first power line VDL for transmitting the first power ELVDD to the light emitting pixel drivers EPD, a second power line for transmitting the second power ELVSS to the light emitting elements LE, a reference voltage line VRL for transmitting the reference voltage VREF to the light emitting pixel drivers EPD, and an initialization voltage line VAIL for transmitting an initialization voltage VAINT to the light emitting pixel drivers EPD.

The light emitting elements LE of the element layer 130 (see FIG. 4) may be electrically connected between the light emitting pixel drivers EPD and a second power source ELVSS.

That is, one of the light emitting elements LE may be electrically connected between one of the light emitting pixel drivers EPD of the circuit layer 120 and the second power source ELVSS.

The second power ELVSS may be at a voltage level lower than that of the first power ELVDD.

That is, the anode electrode of the light emitting element LE is electrically connected to the light emitting pixel driver EPD and the cathode electrode of the light emitting element LE may be applied with the second power ELVSS having a voltage level lower than the first power ELVDD.

A capacitor Cel connected in parallel with the light emitting element LE refers to a parasitic capacitance between the anode electrode and the cathode electrode.

The circuit layer 120 may include the scan write line GWL that transmits the scan write signal GW, the reset control line GRL that transmits the reset control signal GR, the initialization control line GIL that transmits the initialization control signal GI, the first emission control line ECL1 that transmits the first emission control signal EC1, and the second emission control line ECL2 that transmits the second emission control signal EC2.

One light emitting pixel driver EPD of the circuit layer 120 may include a first transistor T1 configured to generate a driving current for driving the light emitting element LE, two or more transistors T2 to T6 electrically connected to the first transistor T1 or the light emitting element LE, and one or more capacitors C1 and C2.

A second transistor T2 may be electrically connected between the gate electrode of the first transistor T1 and the data line DL.

The second transistor T2 may be turned on by the scan write signal GW of the scan write line GWL.

When the second transistor T2 is turned on, the data signal Vdata of the data line DL may be transmitted to the gate electrode of the first transistor T1.

When the voltage difference between the gate electrode of the first transistor T1 and the second electrode of the first transistor T1 is equal to or greater than the threshold voltage of the first transistor T1 due to the data signal Vdata applied to the gate electrode of the first transistor T1, the first transistor T1 may be turned on. Accordingly, a drain-source current of the first transistor T1 may be generated to have a magnitude corresponding to the data signal Vdata.

A third transistor T3 may be electrically connected between the gate electrode of the first transistor T1 and the reference voltage line VRL.

The third transistor T3 may be turned on by the reset control signal GR of the reset control line GRL.

When the third transistor T3 is turned on, the potential of the gate electrode of the first transistor T1 may be reset to the reference voltage VREF of the reference voltage line VRL.

The fourth transistor T4 may be electrically connected between the light emitting element LE and the initialization voltage line VAIL.

The fourth transistor T4 may be turned on by the initialization control signal GI of the initialization control line GIL.

When the fourth transistor T4 is turned on, the potential of the anode electrode of the light emitting element LE may be initialized to the initialization voltage VAINT of the initialization voltage line VAIL.

The fifth transistor T5 may be electrically connected between the first electrode of the first transistor T1 and the first power line VDL.

The fifth transistor T5 may be turned on by the first emission control signal EC1 of the first emission control line ECL1.

When the fifth transistor T5 is turned on, the first power ELVDD of the first power line VDL may be transmitted to the first electrode of the first transistor T1.

The sixth transistor T6 may be electrically connected between the second electrode of the first transistor T1 and the light emitting element LE.

The sixth transistor T6 may be turned on by the second emission control signal EC2 of the second emission control line ECL2.

When the sixth transistor T6 is turned on, the drain-source current of the first transistor T1 generated to have the magnitude corresponding to the data signal Vdata may be transmitted as a driving current to the light emitting element LE through the sixth transistor T6.

Accordingly, the light emitting element LE may emit light having a luminance corresponding to the data signal Vdata.

The first capacitor C1 may be electrically connected between the gate electrode of the first transistor T1 and the second electrode of the first transistor T1.

Accordingly, the first capacitor C1 may be charged with the data signal Vdata applied to the gate electrode of the first transistor T1 and the turn-on of the first transistor T1 may be maintained for a selected period due to the voltage charged in the first capacitor C1.

A second capacitor C2 may be electrically connected between the second electrode of the first transistor T1 and the first power line VDL.

The voltage of the first capacitor C1 may correspond to the potential difference between the gate electrode of the first transistor T1 and the second electrode of the first transistor T1, may be changed by the data signal Vdata, and may be divided by the second capacitor C2. Accordingly, the threshold voltage of the first transistor T1 may be compensated.

According to one embodiment, the first transistor T1 may include a gate electrode and a gate additional electrode facing opposite surfaces of a channel portion.

The gate electrode of the first transistor T1 may be electrically connected to the second transistor T2.

The gate additional electrode of the first transistor T1 may be electrically connected to the second electrode of the first transistor T1.

Accordingly, when the data signal Vdata is applied to the gate electrode of the first transistor T1 such that the first transistor T1 is in a turned-on state, a channel may be formed in an active layer disposed adjacent to the gate electrode and may not be formed in an area disposed adjacent to the gate additional electrode.

Therefore, since the electron mobility in the channel portion of the first transistor T1 decreases, the drain-source current Ids according to the voltage of the gate electrode Vg of the first transistor T1 may become gentle. Accordingly, a driving voltage range of the first transistor T1 may be widened, which may facilitate luminance control.

As illustrated in FIG. 7, the first transistor T1 may be an N-type MOSFET. Further, at least some of the second to sixth transistors T2 to T6 may be P-type MOSFETs. For example, the fifth transistor T5 and the sixth transistor T6 may be P-type MOSFETs, and the second transistor T2, the third transistor T3, and the fourth transistor T4 may be N-type MOSFETs.

Accordingly, according to one embodiment, the circuit layer 120 may include a first semiconductor layer SEL1 (see FIG. 8) for providing a P-type MOSFET and a second semiconductor layer SEL2 (see FIG. 8) for providing an N-type MOSFET.

FIG. 8 is a cross-sectional view illustrating the first transistor, the second transistor, the sixth transistor, the first capacitor, the second capacitor, and the light emitting element of FIG. 7.

Referring to FIG. 8, the display device 100 according to one embodiment may include the substrate 110, the circuit layer 120 on the substrate 110, and the element layer 130 on the circuit layer 120.

The display device 100 may further include the encapsulation layer 140 on the element layer 130.

According to one embodiment, the circuit layer 120 may include the first semiconductor layer SEL1 located on the substrate 110, a first interlayer insulating layer 124 located on the first semiconductor layer SEL1, and the second semiconductor layer SEL2 located on the first interlayer insulating layer 124.

The circuit layer 120 may further include a first gate insulating layer 122 covering the first semiconductor layer SEL1, a first gate conductive layer GCDL1 located on the first gate insulating layer 122, a second gate insulating layer 123 covering the first gate conductive layer GCDL1, a second gate conductive layer GCDL2 located between the second gate insulating layer 123 and the first interlayer insulating layer 124, a third gate insulating layer 125 covering the second semiconductor layer SEL2, a third gate conductive layer GCDL3 located on the third gate insulating layer 125, a second interlayer insulating layer 126 covering the third gate conductive layer GCDL3, a first source-drain conductive layer SDCDL1 located on the second interlayer insulating layer 126, a first planarization layer 127 covering the first source-drain conductive layer SDCDL1, a second source-drain conductive layer SDCDL2 located on the first planarization layer 127, and a second planarization layer 128 covering the second source-drain conductive layer SDCDL2.

According to one embodiment, the circuit layer 120 may further include the buffer layer 121 covering the substrate 110. In this case, the first semiconductor layer SEL1 may be located on the buffer layer 121.

The circuit layer 120 may include light emitting pixel drivers EPD electrically connected to the light emitting elements LE of the element layer 130, respectively.

According to one embodiment, each of the light emitting pixel drivers EPD may include the first transistor T1, the second transistor T2, the third transistor T3, the fourth transistor T4, the fifth transistor T5, and the sixth transistor T6, the first capacitor C1, and the second capacitor C2.

Each of the first transistor T1, the second transistor T2, the third transistor T3, the fourth transistor T4, the fifth transistor T5, and the sixth transistor T6 may include a gate electrode, a channel portion overlapping the gate electrode, a first electrode portion connected to one side of the channel portion, and a second electrode portion connected to the other side of the channel portion.

According to one embodiment, the first transistor T1, the second transistor T2, the third transistor T3, and the fourth transistor T4 may be N-type MOSFETs, and the fifth transistor T5 and the sixth transistor T6 may be P-type MOSFETs.

That is, the channel portion, the first electrode portion, and the second electrode portion of each of the first transistor T1, the second transistor T2, the third transistor T3, and the fourth transistor T4 may be located in the second semiconductor layer SEL2, and the channel portion, the first electrode portion, and the second electrode portion of each of the fifth transistor T5 and the sixth transistor T6 may be located in the first semiconductor layer SEL1.

The sixth transistor T6 may include the channel portion CH6 located in the first semiconductor layer SEL1, the first electrode E16 located in the first semiconductor layer SEL1 and connected to one side of the channel portion CH6, the second electrode E26 located in the first semiconductor layer SEL1 and connected to the other side of the channel portion CH6, and the gate electrode G6 located in the first gate conductive layer GCDL1 and overlapping the channel portion CH6.

The first semiconductor layer SEL1 may include a silicon semiconductor material such as polysilicon or amorphous silicon.

Since the fifth transistor T5 is the same P-type MOSFET as the sixth transistor T6, redundant descriptions will be omitted below.

The first transistor T1 and the second transistor T2 may include channel portions CH1 and CH2 located in the second semiconductor layer SEL2, first electrodes E11 and E12 located in the second semiconductor layer SEL2 and connected to one sides of the channel portions CH1 and CH2, second electrodes E21 and E22 located in the second semiconductor layer SEL2 and connected to the other sides of the channel portions CH1 and CH2, and gate electrodes G1 and G2 located in the third gate conductive layer GCDL3 and overlapping the channel portions CH1 and CH2, respectively.

The second semiconductor layer SEL2 may include an oxide semiconductor material.

The first gate conductive layer GCDL1 may include a first capacitor electrode CAE1 and a second capacitor electrode CAE2 that are spaced apart from each other.

The second gate conductive layer GCDL2 may include a third capacitor electrode CAE3 overlapping the first capacitor electrode CAE1 and the second capacitor electrode CAE2.

The top surface of the channel portion CH1 of the first transistor T1 may face the gate electrode G1.

In addition, the bottom surface of the channel portion CH1 of the first transistor T1 may face the third capacitor electrode CAE3 electrically connected to the second electrode E21 of the first transistor T1.

That is, the third capacitor electrode CAE3 may be a gate additional electrode of the first transistor T1.

The first electrode E12 of the second transistor T2 may be electrically connected to the data line DL through a data connection electrode DCE.

The data connection electrode DCE may be located in the first source-drain conductive layer SDCDL1 and may be electrically connected to the first electrode E12 of the second transistor T2 through a data connection hole DCH.

The data connection hole DCH may penetrate the second interlayer insulating layer 126 and the third gate insulating layer 125.

The data line DL may be located in the second source-drain conductive layer SDCDL2, and may be electrically connected to the data connection electrode DCE through a data connection additional hole DCAH penetrating the first planarization layer 127.

The first source-drain conductive layer SDCDL1 may include a first node connection electrode NCE1, a second node connection electrode NCE2, the data connection electrode DCE, and a first anode connection electrode ANCE1.

The second source-drain conductive layer SDCDL2 may include a second anode connection electrode ANCE2, the data line DL, and a power additional line VDAL.

The second electrode E22 of the second transistor T2 may be electrically connected to the gate electrode G1 of the first transistor T1 and the first capacitor electrode CAE1 through the first node connection electrode NCE1.

The first node connection electrode NCE1 may be electrically connected to the gate electrode G1 of the first transistor T1 through the first node connection hole NCH1, electrically connected to the first capacitor electrode CAE1 through the second node connection hole NCH2, and electrically connected to the second electrode E22 of the second transistor T2 through the third node connection hole NCH3.

The second electrode E21 of the first transistor T1 may be electrically connected to the first electrode E16 of the sixth transistor T6 and the third capacitor electrode CAE3 through the second node connection electrode NCE2.

The second node connection electrode NCE2 may be electrically connected to the second electrode E21 of the first transistor T1 through a fourth node connection hole NCH4, electrically connected to the third capacitor electrode CAE3 through a fifth node connection hole NCH5, and electrically connected to the first electrode E16 of the sixth transistor T6 through a sixth node connection hole NCH6.

The second capacitor electrode CAE2 may be located in the first gate conductive layer GCDL1 on the first gate insulating layer 122.

The first capacitor electrode CAE1 is electrically connected to the gate electrode G1 of the first transistor T1, and the third capacitor electrode CAE3 is electrically connected to the second electrode E21 of the first transistor T1. Accordingly, the first capacitor C1 may be formed in the region where the first capacitor electrode CAE1 and the third capacitor electrode CAE3 overlap each other.

The first power line VDL (see FIG. 7) may be located in the first gate conductive layer GCDL1.

The second capacitor electrode CAE2 may be a part of the first power line VDL (see FIG. 7).

The power additional line VDAL may extend in a direction intersecting the first power line VDL and may be electrically connected to the first power line VDL.

For example, the first power line VDL may extend in the first direction DR1 and the power additional line VDAL may extend in the second direction DR2.

Therefore, the first power ELVDD (see FIG. 7) may be transmitted to the display area DA (see FIG. 3) through a mesh-shaped line including the first power line VDL and the power additional line VDAL.

The second capacitor electrode CAE2 may be a part of the first power line VDL (see FIG. 7) that transmits the first power ELVDD (see FIG. 7) and the third capacitor electrode CAE3 may be electrically connected to the second electrode E21 of the first transistor T1 through the second node connection electrode NCE2. Therefore, the second capacitor C2 may be formed in a region where the second capacitor electrode CAE2 and the third capacitor electrode CAE3 overlap each other.

The second electrode E26 of the sixth transistor T6 may be electrically connected to the anode electrode 131 of the light emitting element LE through the first anode connection electrode ANCE1 and the second anode connection electrode ANCE2.

The first anode connection electrode ANCE1 may be electrically connected to the second electrode E26 of the sixth transistor T6 through a first anode connection hole ANCH1.

The first anode connection hole ANCH1 may penetrate the second interlayer insulating layer 126, the third gate insulating layer 125, the first interlayer insulating layer 124, the second gate insulating layer 123, and the first gate insulating layer 122.

The second anode connection electrode ANCE2 may be electrically connected to the first anode connection electrode ANCE1 through a second anode connection hole ANCH2 penetrating the first planarization layer 127.

The anode electrode 131 may be located on the second planarization layer 128, and may be electrically connected to the second anode connection electrode ANCE2 through a third anode connection hole ANCH3.

The element layer 130 may be located on the circuit layer 120 and may include the light emitting elements LE respectively disposed in an area corresponding to the emission areas EA.

Each of the light emitting elements LE may include the anode electrode 131 and a cathode electrode 134 facing each other, and a light emitting layer 133 located between the anode electrode 131 and the cathode electrode 134.

That is, the element layer 130 may include the anode electrode 131 located in the emission areas EA, a pixel defining layer 132 located in the non-emission area and covering the edge of the anode electrode 131, the light emitting layer 133 located on the anode electrode 131, and the cathode electrode 134 located on the light emitting layers 133 and the pixel defining layer 132.

The pixel defining layer 132 may include a first pixel defining layer 1321 located on the second planarization layer 128, a second pixel defining layer 1322 located on the first pixel defining layer 1321, and a spacer layer 1323 located on a portion of the second pixel defining layer 1322.

As an example, the first pixel defining layer 1321 may include a light-absorbing insulating material that absorbs light or a light-blocking insulating material that blocks light.

Alternatively, each of the light emitting elements LE may further include a first common layer located between the anode electrode 131 and the light emitting layer 133, and a second common layer located between the light emitting layer 133 and the cathode electrode 134.

The anode electrode 131 may be located in the emission area EA and may be electrically connected to the light emitting pixel driver EPD. This anode electrode 131 may be referred to as a pixel electrode.

The light emitting layer 133 may include an organic light emitting material that converts electron-hole pairs into light.

The cathode electrode 134 may be located in the display area (see FIG. 3) including the emission areas EA. The cathode electrode 134 may be a part of a second power line VSL (see FIG. 7) that transmits the second power ELVSS (see FIG. 7) or may be electrically connected to the second power line VSL. The cathode electrode 134 may be referred to as a common electrode.

The encapsulation layer 140 may be located on the circuit layer 120 and cover the element layer 130.

As an example, the encapsulation layer 140 may include a first encapsulation layer located on the element layer 130 and containing an inorganic insulating material, a second encapsulation layer located on the first encapsulation layer, overlapping the element layer 130, and containing an organic insulating material, and a third encapsulation layer located on the first encapsulation layer, covering the second encapsulation layer, and containing an inorganic insulating material.

FIG. 9 is a plan view illustrating the substrate of FIG. 4 according to one embodiment.

Referring to FIG. 9, the substrate 110 of the display device 100 according to one embodiment includes the main region MA corresponding to the display surface and the sub-region SBA protruding from a part of one side of the main region MA.

The main region MA may include the display area DA located at the center, and the non-display area NDA located at the periphery to surround the display area DA.

The display area DA may include a bypass area BYA located on one side adjacent to the sub-region SBA, and a general area GA located in the remaining area excluding the bypass area BYA.

The bypass area BYA may include a bypass middle area BMA located at the center in the first direction DR1, a first bypass side area BSA1 extending parallel to the bypass middle area BMA and in contact with the non-display area NDA, and a second bypass side area BSA2 extending parallel to the bypass middle area BMA and the first bypass side area BSA1, and located between the bypass middle area BMA and the first bypass side area BSA1.

The first bypass side area BSA1 may be located adjacent to the bent corner of the substrate 110 as compared to the bypass middle area BMA and the second bypass side area BSA2.

The first bypass side area BSA1 and the second bypass side area BSA2 may be located between the non-display area NDA and each of opposite sides of the bypass middle area BMA in the first direction DR1.

The general area GA may include a general middle area GMA connected to the bypass middle area BMA of the bypass area BYA in the second direction DR2, a first general side area GSA1 connected to the first bypass side area BSA1 of the bypass area BYA in the second direction DR2, and a second general side area GSA2 connected to the second bypass side area BSA2 of the bypass area BYA in the second direction DR2.

The non-display area NDA may include a gate driving circuit area GDRA where the gate driving circuit GTDR (see FIG. 6) is located.

The gate driving circuit area GDRA may face one side of the display area DA extending in the second direction DR2. However, this is merely an example and the gate driving circuit area GDRA may be located separately in the display area DA rather than the non-display area NDA.

The gate driving circuit GTDR of the gate driving circuit area GDRA may transmit gate signals to gate lines.

The gate lines may include the scan write line GWL (see FIG. 7), the reset control line GRL (see FIG. 7), the initialization control line GIL (see FIG. 7), the first emission control line ECL1 (see FIG. 7), and the second emission control line ECL2 (see FIG. 7).

The sub-region SBA may include the bending area BA that may be bent, a first sub-region SB1 located between one side of the bending area BA and the main region MA, and a second sub-region SB2 connected to the other side of the bending area BA.

When the bending area BA is bent, the second sub-region SB2 is located below the substrate 110 and overlaps the main region MA.

The display driving circuit 200 may be located in the second sub-region SB2.

The signal pads SPD bonded to the circuit board 300 (see FIG. 3) may be arranged at one edge of the second sub-region SB2.

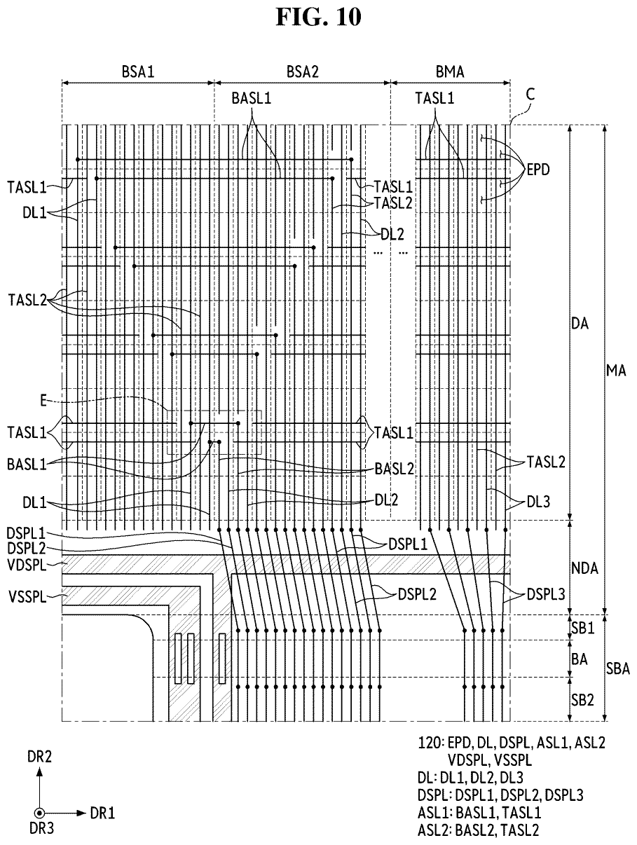

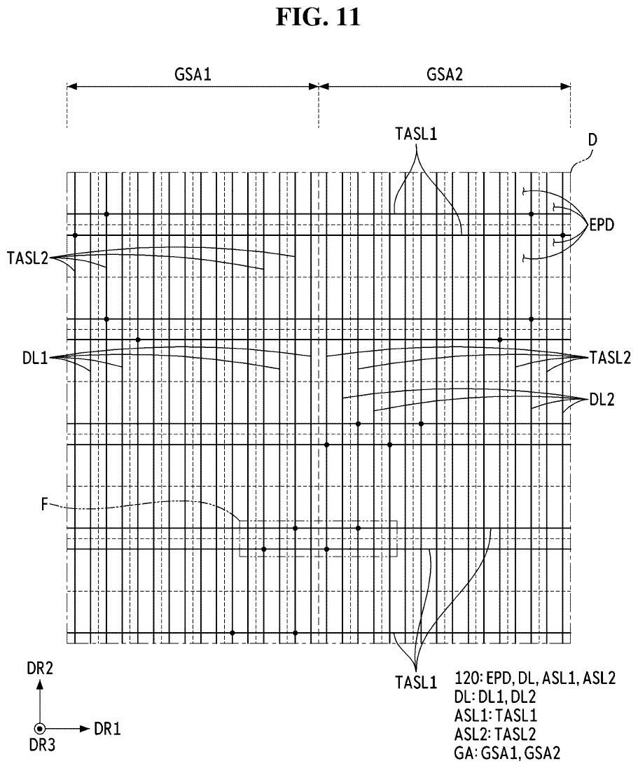

FIG. 10 is a schematic diagram showing part C of FIG. 9. FIG. 11 is a schematic diagram showing part D of FIG. 9.

Referring to FIGS. 10 and 11, the circuit layer 120 of the display device 100 according to one embodiment may include the light emitting pixel drivers EPD arranged side by side with each other in the first direction DR1 and the second direction DR2, the data lines DL extending in the second direction DR2 and transmitting the data signal Vdata (see FIG. 7) to the light emitting pixel drivers EPD, first auxiliary lines ASL1 extending in the first direction DR1, and second auxiliary lines ASL2 extending in the second direction DR2 and adjacent to the data lines DL.

The circuit layer 120 may further include data supply lines DSPL located in the non-display area NDA and electrically connected between the display driving circuit 200 and the data lines DL.

The data supply lines DSPL may extend to the bypass middle area BMA and the second bypass side area BSA2.

The data supply lines DSPL may include a first data supply line DSPL1 that transmits the data signal of the first data line DL1, and a second data supply line DSPL2 that transmits the data signal of the second data line DL2.

The data lines DL may include the first data line DL1 located in the first bypass side area BSA1 which is adjacent to the non-display area NDA in the first direction DR1 and the second data line DL2 located in the second bypass side area BSA2 between the first bypass side area BSA1 and the bypass middle area BMA.

The first auxiliary lines ASL1 may include a first bypass auxiliary line BASL1 electrically connected to the first data line DL1.

The second auxiliary lines ASL2 may include a second bypass auxiliary line BASL2 electrically connected to the first bypass auxiliary line BASL1.

The first bypass auxiliary line BASL1 may electrically connect the first data line DL1 and the second bypass auxiliary line BASL2.

The second bypass auxiliary line BASL2 may electrically connect the first bypass auxiliary line BASL1 and the first data supply line DSPL1.

That is, the first data supply line DSPL1 may extend to the second bypass auxiliary line BASL2 in the second bypass side area BSA2, and may be electrically connected to the first data line DL1 through the second bypass auxiliary line BASL2 and the first bypass auxiliary line BASL1.

On the other hand, the second data supply line DSPL2 may extend to the second bypass side area BSA2 and may be directly electrically connected to the second data line DL2 in the second bypass side area BSA2.

In this way, since the first data supply line DSPL1 extends not to the first data line DL1 in the first bypass side area BSA1 but to the second bypass auxiliary line BASL2 in the second bypass side area BSA2, the extension length of the first data supply line DSPL1 may be shortened. As a result, the width of the area required for the arrangement of the data supply lines DSPL may be reduced, so that the width of the non-display area NDA may be reduced.

In addition, since the data supply lines DSPL are not located in a portion of the non-display area NDA adjacent to the bent edge of the substrate 110, the width of the non-display area NDA may be further reduced.

The data lines DL may further include a third data line DL3 located in the bypass middle area BMA. In addition, the data supply lines DSPL may further include a third data supply line DSPL3 that transmits the data signal of the third data line DL3.

The third data supply line DSPL3 may extend to the bypass middle area BMA, and may be electrically connected directly to the third data line DL3.

The first auxiliary lines ASL1 may further include first transmission auxiliary lines TASL1 in addition to the first bypass auxiliary line BASL1.

The second auxiliary lines ASL2 may further include second transmission auxiliary lines TASL2 in addition to the second bypass auxiliary lines BASL2.

The first bypass auxiliary line BASL1 may be connected between the first data line DL1 and the second bypass auxiliary line BASL2.

The second bypass auxiliary line BASL2 may be connected between the first data supply line DSPL1 and the first bypass auxiliary line BASL1, and extending from the display area DA to the non-display area NDA.

In this way, since the first bypass auxiliary line BASL1 and the second bypass auxiliary line BASL2 are located in the bypass area BYA in a limited manner, and the ends of the first bypass auxiliary line BASL1 and the ends of the second bypass auxiliary line BASL2 are located in the display area DA, the first bypass auxiliary line BASL1 and the second bypass auxiliary line BASL2 may be recognized by the user, thus deteriorate the visibility of the display area DA.

To prevent this, the first auxiliary lines ASL1 may further include not only the first bypass auxiliary line BASL1 but also first transmission auxiliary lines TASL1. Also, the second auxiliary lines ASL2 may further include not only the second bypass auxiliary line BASL2 but also the second transmission auxiliary lines TASL2.

Two of the first transmission auxiliary lines TASL1 may extend from opposite ends of the first bypass auxiliary line BASL1 to the non-display area NDA.

One of the second transmission auxiliary lines TASL2 may extend from one end of the second bypass auxiliary line BASL2 to the non-display area NDA in a direction away from the sub-region SBA.

Since the second bypass auxiliary lines BASL2 are located only in the second bypass side area BSA2, each of the first data line DL1 in the first bypass side area BSA1 and the third data line DL3 in the bypass middle area BMA may be entirely adjacent to the second transmission auxiliary lines TASL2.

According to one embodiment, each of the first transmission auxiliary lines TASL1 and the second transmission auxiliary lines TASL2 may be electrically connected to one of the first power line VDL (see FIG. 7) transmitting the first power ELVDD (see FIG. 7), the second power line VSL (see FIG. 7) transmitting the second power ELVSS (see FIG. 7), the initialization voltage line VAIL (see FIG. 7) transmitting the initialization voltage VAINT (see FIG. 7), and the reference voltage line VRL (see FIG. 7) transmitting the reference voltage VREF (see FIG. 7). In this way, the resistance of conductive lines through which power and/or a constant voltage is transmitted may be reduced by the first transmission auxiliary lines TASL1 and the second transmission auxiliary lines TASL2.

According to one embodiment, the circuit layer 120 may further include a first power supply line VDSPL and a second power supply line VSSPL that are located in the non-display area NDA and extend to the sub-region SBA.

The first power supply line VDSPL transmits the first power ELVDD (see FIG. 7), and the second power supply line VSSPL transmits the second power ELVSS (see FIG. 7).

The first power supply line VDSPL may be electrically connected to a first power pad for transmitting the first power ELVDD (see FIG. 7) among the signal pads SPD (see FIG. 9) located in the second sub-region SB2.

The second power supply line VSSPL (see FIG. 7) may be electrically connected to a second power pad for transmitting the second power ELVSS (see FIG. 7) among the signal pads SPD (see FIG. 9) located in the second sub-region SB2.

For example, at least some of the first transmission auxiliary lines TASL1 may be electrically connected to the second power supply line VSSPL.

In addition, at least some of the second transmission auxiliary lines TASL2 may be electrically connected to at least some of the first transmission auxiliary lines TASL1 and the second power supply line VSSPL.

As shown in FIG. 11, the first transmission auxiliary lines TASL1 of the first auxiliary lines ASL1 and the second transmission auxiliary lines TASL2 of the second auxiliary lines ASL2 may be located in the general area GA.

Each of the first transmission auxiliary lines TASL1 may be electrically connected to at least some of the second transmission auxiliary lines TASL2.

As illustrated in FIGS. 10 and 11, according to one embodiment, the first auxiliary lines ASL1 may be arranged in pairs.

Among the first auxiliary lines ASL1, two first auxiliary lines ASL1 adjacent in the second direction DR2 may be located adjacent to the boundary between two light emitting pixel drivers EPD adjacent in the second direction DR2.

That is, according to one embodiment, since the first auxiliary lines ASL1 are arranged in pairs rather than one by one at equal intervals, the width of the area that should be ensured for the arrangement of the first auxiliary lines ASL1 may be reduced.

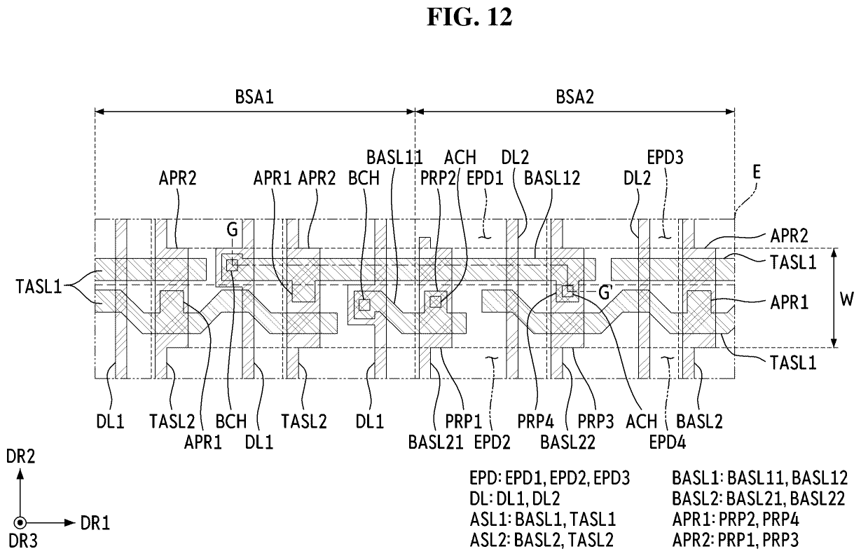

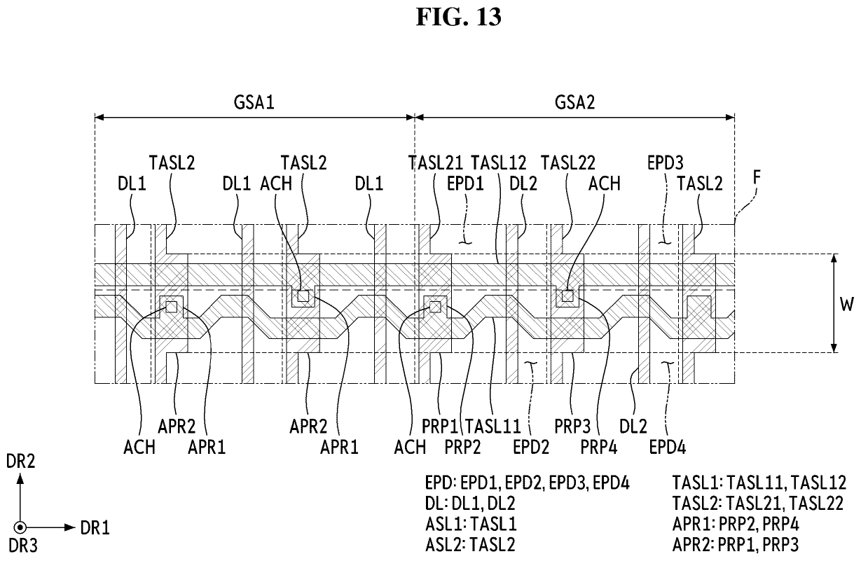

FIG. 12 is a plan view illustrating part E of FIG. 10. FIG. 13 is a plan view showing part F of FIG. 11.

Referring to FIGS. 12 and 13, the circuit layer 120 of the display device 100 according to one embodiment may include the light emitting pixel drivers EPD arranged side by side with each other in the first direction DR1 and the second direction DR2, the data lines DL extending in the second direction DR2 and transmitting the data signal Vdata (see FIG. 7), the first auxiliary lines ASL1 extending in the first direction DR1, and the second auxiliary lines ASL2 extending in the second direction DR2 and adjacent to the data lines DL.

The first auxiliary lines ASL1 may be arranged in pairs at the boundary between the light emitting pixel drivers EPD adjacent in the second direction DR2.

Each of the light emitting pixel drivers EPD may overlap a first auxiliary protrusion APR1 extending from one of two first auxiliary lines ASL1 adjacent in the second direction DR2.

The second auxiliary lines ASL2 may be alternately arranged with the data lines DL in the first direction DR1. That is, each of the light emitting pixel drivers EPD may intersect one data line DL and one second auxiliary line ASL2.

Each of the second auxiliary lines ASL2 may include a second auxiliary protrusion APR2 overlapping two first auxiliary lines ASL1 adjacent in the second direction DR2.

The second auxiliary protrusion APR2 may further overlap the first auxiliary protrusion APR1 extending from one of two first auxiliary lines ASL1.

The first auxiliary protrusion APR1 and the second auxiliary protrusion APR2 may be located in an intersection area between the first auxiliary lines ASL1 and the second auxiliary lines ASL2.

According to one embodiment, the second auxiliary protrusions APR2 of the second auxiliary lines ASL2 may be arranged side by side with each other in the first direction DR1 and arranged with the same width W in the second direction DR2.

In this way, regardless of the irregular arrangement of the first auxiliary protrusions APR1, the irregularly arranged first auxiliary protrusions APR1 may not be recognized by a user by regularly arranging the second auxiliary protrusions APR2. Accordingly, the deterioration of the display quality of the display device 100 due to the irregular arrangement of the first auxiliary protrusions APR1 may be prevented.

According to one embodiment, the light emitting pixel drivers EPD may include a first light emitting pixel driver EPD1 and a second light emitting pixel driver EPD2 adjacent to each other in the second direction DR2.

Among the first auxiliary lines ASL1, two first auxiliary lines BASL11 and BASL12 adjacent in the second direction DR2 may intersect the first light emitting pixel driver EPD1 or the second light emitting pixel driver EPD2, and may be located adjacent to the boundary between the first light emitting pixel driver EPD1 and the second light emitting pixel driver EPD2.

The second auxiliary lines ASL2 may include one second auxiliary line BASL21 intersecting the first light emitting pixel driver EPD1 and the second light emitting pixel driver EPD2.

One second auxiliary line BASL21 may include a first protrusion PRP1 overlapping two first auxiliary lines BASL11 and BASL12.

The first protrusion PRP1 may further overlap a second protrusion PRP2 extending from one first auxiliary line BASL11 of two first auxiliary lines BASL11 and BASL12.

That is, the second auxiliary protrusions APR2 may include the first protrusion PRP1 located in an intersection area between two first auxiliary lines BASL11 and BASL12 and one second auxiliary line BASL21.

The first auxiliary protrusions APR1 may include the second protrusion PRP2 located in an intersection area between one first auxiliary line BASL11 of two first auxiliary lines BASL11 and BASL12 and one second auxiliary line BASL21.

The second protrusion PRP2 may face the other first auxiliary line BASL12 of two first auxiliary lines BASL11 and BASL12 in the second direction DR2.

The first protrusion PRP1 extending from one second auxiliary line BASL21 may overlap two first auxiliary lines BASL11 and BASL12, and the second protrusion PRP2 extending from one first auxiliary line BASL11 of two first auxiliary lines BASL11 and BASL12.

According to one embodiment, the light emitting pixel drivers EPD may further include a third light emitting pixel driver EPD3 and a fourth light emitting pixel driver EPD4 adjacent to the first light emitting pixel driver EPD1 and the second light emitting pixel driver EPD2 in the first direction DR1, respectively.

The two first auxiliary lines BASL11 and BASL12 may extend in the first direction DR1 to intersect the third light emitting pixel driver EPD3 or the fourth light emitting pixel driver EPD4 and may be located adjacent to the boundary between the third light emitting pixel driver EPD3 and the fourth light emitting pixel driver EPD4.

The second auxiliary lines ASL2 may further include another second auxiliary line BASL22 intersecting the third light emitting pixel driver EPD3 and the fourth light emitting pixel driver EPD4.

The another second auxiliary line BASL22 may include a third protrusion PRP3 overlapping two first auxiliary lines BASL12 and TASL1.

The third protrusion PRP3 may further overlap a fourth protrusion PRP4 extending from the other first auxiliary line BASL12 of two first auxiliary lines BASL11 and BASL12.

That is, the second auxiliary protrusions APR2 may further include the third protrusion PRP3 located in an intersection area between two first auxiliary lines BASL12 and TASL1 and another second auxiliary line BASL22.

The first auxiliary protrusions APR1 may further include the fourth protrusion PRP4 located in an intersection area between the other first auxiliary line BASL12 of two first auxiliary lines BASL12 and TASL1and another second auxiliary line BASL22.

The fourth protrusion PRP4 may face one first auxiliary line TASL1 of two first auxiliary lines BASL12 and TASL1 in the second direction DR2.

The third protrusion PRP3 extending from another second auxiliary line BASL22 may overlap two first auxiliary lines BASL12 and TASL1 and the fourth protrusion PRP4 extending from the other first auxiliary line BASL12 of the two first auxiliary lines BASL12 and TASL1.

According to one embodiment, the second auxiliary protrusions APR2 may be arranged side by side in the first direction DR1 and arranged with the same width W in the second direction DR2.

That is, the first protrusion PRP1 and the third protrusion PRP3 may be arranged with the same width W in the second direction DR2 and arranged side by side in the first direction DR1.

In other words, the second auxiliary protrusions APR2 may have the same size in the second direction DR2 and be arranged at regular intervals in the first direction DR1.

According to one embodiment, an auxiliary connection hole ACH for electrical connection between the first auxiliary line ASL1 and the second auxiliary line ASL2 may overlap the first auxiliary protrusion APR1 and the second auxiliary protrusion APR2.

That is, the auxiliary connection hole ACH for electrical connection between one first auxiliary line BASL11 and one second auxiliary line BASL21 may overlap the second protrusion PRP2 and the first protrusion PRP1.

The auxiliary connection hole ACH for electrical connection between the other first auxiliary line BASL12 and another second auxiliary line BASL22 may overlap the fourth protrusion PRP4 and the third protrusion PRP3.

In addition, the first bypass auxiliary line BASL1 may be electrically connected to the first data line DL1 through a bypass connection hole BCH.

As described above, according to one embodiment, the first auxiliary protrusions APR1 may not be respectively located at every intersection areas between the light emitting pixel drivers EPD and the first auxiliary lines ASL1, but may be alternately arranged at intersection areas between one of two light emitting pixel drivers EPD and one of two first auxiliary lines ASL1, and thus may be arranged in a zigzag shape in a plan view.

That is, the second protrusion PRP2 extended from one first auxiliary line BASL11 and the fourth protrusion PRP4 extended from the other first auxiliary line BASL12 may face each other in a diagonal direction crossing the first direction DR1 and the second direction DR2, rather than in the first direction DR1 and the second direction DR2.

In this way, the number of first auxiliary protrusions APR1 located in the display area DA may be reduced to half the number of intersection areas between the light emitting pixel drivers EPD and the first auxiliary lines ASL1, so that it may be advantageous for reducing the width of each of the light emitting pixel drivers EPD. Accordingly, it may be advantageous for achieving high resolution of the display device 100.

Additionally, according to one embodiment, the first auxiliary protrusions APR1 are arranged irregularly in the first direction DR1 and the second direction DR2, but the second auxiliary protrusions APR2 are arranged regularly in the first direction DR1 and the second direction DR2 and overlap the first auxiliary protrusions APR1.

Accordingly, the first auxiliary protrusions APR1 may be covered by the second auxiliary protrusions APR2, so that the irregularly arranged first auxiliary protrusions APR1 may not be recognized by the user. Accordingly, the deterioration of the display quality of the display device 100 due to a decrease in the number of first auxiliary protrusions APR1 may be prevented.

As illustrated in FIG. 12, the first auxiliary lines ASL1 may include two first transmission auxiliary lines TASL1 facing opposite sides of the first bypass auxiliary line BASL1 in the first direction DR1.

FIG. 12 illustrates a case where the first light emitting pixel driver EPD1, the second light emitting pixel driver EPD2, the third light emitting pixel driver EPD3, and the fourth light emitting pixel driver EPD4 are arranged in the second bypass side area BSA2.

FIG. 13 illustrates a case where the first light emitting pixel driver EPD1, the second light emitting pixel driver EPD2, the third light emitting pixel driver EPD3, and the fourth light emitting pixel driver EPD4 are arranged in the second general side area GSA2.

As illustrated in FIG. 13, the general area GA is substantially the same as the bypass area BYA except that the first bypass auxiliary line BASL1 and the second bypass auxiliary line BASL2 are not located and only the first transmission auxiliary lines TASL1 and the second transmission auxiliary lines TASL2 are located, so that redundant description is omitted below.

As illustrated in FIG. 13, the light emitting pixel drivers EPD may include the first light emitting pixel driver EPD1 and the second light emitting pixel driver EPD2 adjacent in the second direction DR2, and the third light emitting pixel driver EPD3 and the fourth light emitting pixel driver EPD4 respectively adjacent to the first light emitting pixel driver EPD1 and the second light emitting pixel driver EPD2 in the first direction DR1.

Among the first auxiliary lines ASL1, two first auxiliary lines TASL11 and TASL12 adjacent in the second direction DR2 may intersect the first light emitting pixel driver EPD1 or the second light emitting pixel driver EPD2, and may be located adjacent to the boundary between the first light emitting pixel driver EPD1 and the second light emitting pixel driver EPD2.

Additionally, the two first auxiliary lines TASL11 and TASL12 may intersect the third light emitting pixel driver EPD3 or the fourth light emitting pixel driver EPD4, and may be located adjacent to the boundary between the third light emitting pixel driver EPD3 and the fourth light emitting pixel driver EPD4.

The second auxiliary lines ASL2 may include one second auxiliary line TASL21 intersecting the first light emitting pixel driver EPD1 and the second light emitting pixel driver EPD2, and the other second auxiliary line TASL22 intersecting the third light emitting pixel driver EPD3 and the fourth light emitting pixel driver EPD4.

One second auxiliary line TASL21 may include the first protrusion PRP1 overlapping two first auxiliary lines TASL11 and TASL12.

The first protrusion PRP1 may further overlap the second protrusion PRP2 extending from one first auxiliary line TASL11 of two first auxiliary lines TASL11 and TASL12.

The other second auxiliary line TASL22 may include the third protrusion PRP3 overlapping two first auxiliary lines TASL11 and TASL12.

The third protrusion PRP3 may further overlap the fourth protrusion PRP4 extending from the other first auxiliary line TASL12 of two first auxiliary lines TASL11 and TASL12.

In this way, since the number of first auxiliary protrusions APR1 located in the display area DA may be reduced, it may be advantageous for achieving high resolution of the display device 100 while the irregularly arranged first auxiliary protrusions APR1 may be covered by the second auxiliary protrusions APR2, so that the deterioration of the display quality of the display device 100 may be prevented.

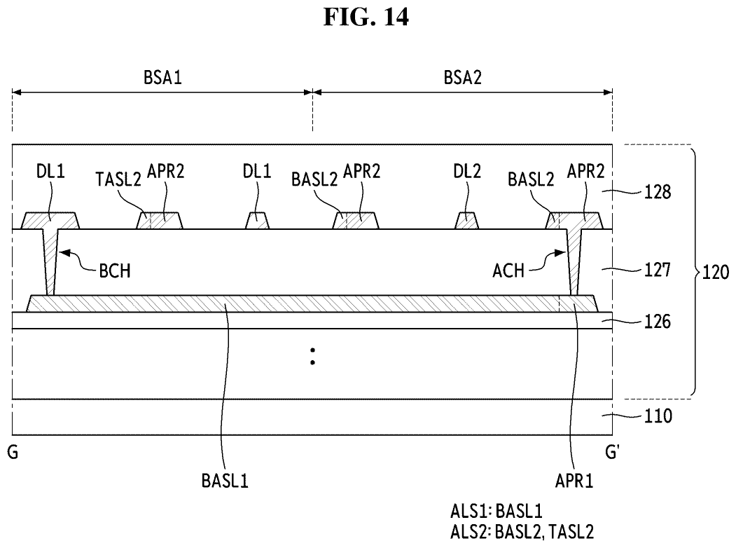

FIG. 14 is a cross-sectional view taken along line G-G′ of FIG. 12.

As illustrated in FIG. 14, according to one embodiment, the first auxiliary lines ASL1 may be located in the first source-drain conductive layer SDCDL1 (see FIG. 8) on the second interlayer insulating layer 126, and the data lines DL and the second auxiliary lines ASL2 may be located in the second source-drain conductive layer SDCDL2 (see FIG. 8) on the first planarization layer 127 covering the first source-drain conductive layer SDCDL1 (see FIG. 8).

The first bypass auxiliary line BASL1 may be electrically connected to the first data line DL1 through the bypass connection hole BCH, and may be electrically connected to the second bypass auxiliary line BASL2 through the auxiliary connection hole ACH.

The auxiliary connection hole ACH may overlap the first auxiliary protrusion APR1 extending from the first bypass auxiliary line BASL1 and the second auxiliary protrusion APR2 extending from the second bypass auxiliary line BASL2.

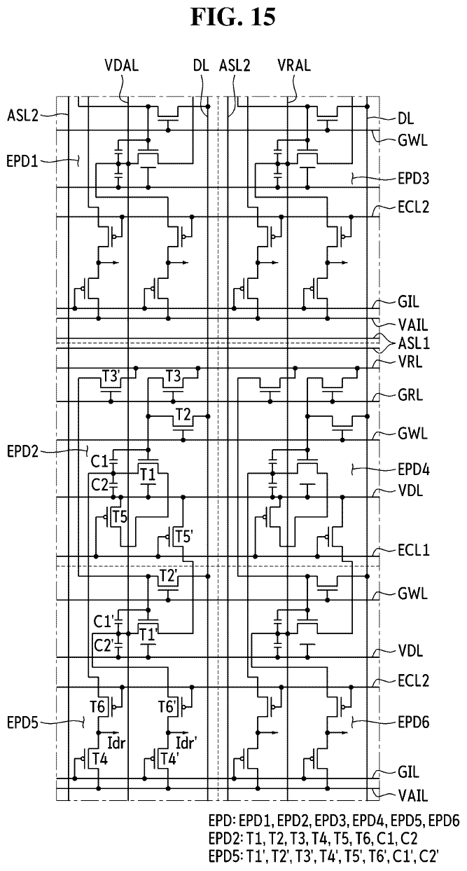

FIG. 15 is a schematic diagram illustrating the arrangement of the lines of FIG. 7 according to one embodiment.

FIG. 15 illustrates six light emitting pixel drivers EPD arranged in a 2×3 configuration and adjacent in the first direction DR1 or the second direction DR2.

As illustrated in FIG. 15, according to one embodiment, the light emitting pixel drivers EPD may include the first light emitting pixel driver EPD1 and the second light emitting pixel driver EPD2 adjacent to each other in the second direction DR2, the third light emitting pixel driver EPD3 and the fourth light emitting pixel driver EPD4 respectively adjacent to the first light emitting pixel driver EPD1 and the second light emitting pixel driver EPD2 in the first direction DR1, and a fifth light emitting pixel driver EPD5 adjacent to the second light emitting pixel driver EPD2 in the second direction DR2.

The light emitting pixel drivers EPD may further include a sixth light emitting pixel driver EPD6 adjacent to the fourth light emitting pixel driver EPD4 in the second direction DR2.

According to one embodiment, the circuit layer 120 (see FIG. 4) may include the first power line VDL for transmitting the first power ELVDD to the light emitting pixel drivers EPD, the second power line VSL (see FIG. 7) for transmitting the second power ELVSS to the light emitting elements LE, the reference voltage line VRL for transmitting the reference voltage VREF to the light emitting pixel drivers EPD, and the initialization voltage line VAIL for transmitting the initialization voltage VAINT to the light emitting pixel drivers EPD.

Further, the circuit layer 120 may include the scan write line GWL that transmits the scan write signal GW, the reset control line GRL that transmits the reset control signal GR, the initialization control line GIL that transmits the initialization control signal GI, the first emission control line ECL1 that transmits the first emission control signal EC1, and the second emission control line ECL2 that transmits the second emission control signal EC2.

According to one embodiment, the first power line VDL may extend in the first direction DR1.

According to one embodiment, the circuit layer 120 may further include the power additional line VDAL extending in the second direction DR2 intersecting the first power line VDL and electrically connected to the first power line VDL.

In this way, the first power ELVDD (see FIG. 7) may be transmitted to the display area DA (see FIG. 3) through mesh-shaped lines including the first power line VDL and the power additional line VDAL.

The scan write line GWL may extend in the first direction DR1.

Each of the light emitting pixel drivers EPD may intersect the scan write line GWL.

According to one embodiment, each of the reference voltage line VRL, the reset control line GRL, the first emission control line ECL1, the second emission control line ECL2, the initialization control line GIL, and the initialization voltage line VAIL may extend in the first direction DR1.

According to one embodiment, some of the reference voltage line VRL, the reset control line GRL, the first emission control line ECL1, the second emission control line ECL2, the initialization control line GIL, and the initialization voltage line VAIL may intersect the second light emitting pixel driver EPD2, and some others may intersect the fifth light emitting pixel driver EPD5.

For example, as illustrated in the diagram of FIG. 15, the reference voltage line VRL, the reset control line GRL, and the first light emitting control line ECL1 may intersect the second light emitting pixel driver EPD2, and the second light emitting control line ECL2, the initialization control line GIL, and the initialization voltage line VAIL may intersect the fifth light emitting pixel driver EPD5.

According to one embodiment, a third transistor T3′ of the fifth light emitting pixel driver EPD5 may be electrically connected to the reference voltage line VRL and the reset control line GRL intersecting the second light emitting pixel driver EPD2.

A fifth transistor T5′ of the fifth light emitting pixel driver EPD5 may be electrically connected to the first light emitting control line ECL1 intersecting the second light emitting pixel driver EPD2.

Accordingly, the third transistor T3′ and the fifth transistor T5′ of the fifth light emitting pixel driver EPD5 may be respectively adjacent to the third transistor T3 and the fifth transistor T5 of the second light emitting pixel driver EPD2 in the first direction DR1.

According to one embodiment, the fourth transistor T4 of the second light emitting pixel driver EPD2 may be electrically connected to the initialization control line GIL and the initialization voltage line VAIL intersecting the fifth light emitting pixel driver EPD5.

The sixth transistor T6 of the second light emitting pixel driver EPD2 may be electrically connected to the second light emitting control line ECL2 intersecting the fifth light emitting pixel driver EPD5.

Accordingly, the fourth transistor T4 and the sixth transistor T6 of the second light emitting pixel driver EPD2 may be respectively adjacent to a fourth transistor T4′ and a sixth transistor T6′ of the fifth light emitting pixel driver EPD5 in the first direction DR1.

That is, the reference voltage line VRL, the reset control line GRL, the first emission control line ECL1, the second emission control line ECL2, the initialization control line GIL, and the initialization voltage line VAIL may not intersect each of the light emitting pixel drivers EPD, but may intersect only two light emitting pixel drivers EPD.

Accordingly, compared to a case where the reference voltage line VRL, the reset control line GRL, the first emission control line ECL1, the second emission control line ECL2, the initialization control line GIL, and the initialization voltage line VAIL intersect each of the light emitting pixel drivers EPD, the number of each of the reference voltage line VRL, the reset control line GRL, the first emission control line ECL1, the second emission control line ECL2, the initialization control line GIL, and the initialization voltage line VAIL located in the display area DA may be reduced by half.

Accordingly, the width of each of the light emitting pixel drivers EPD may be reduced, which may be advantageous for achieving high resolution of the display device 100.

The display device 100 of each embodiment as described above may be applied to various electronic devices.

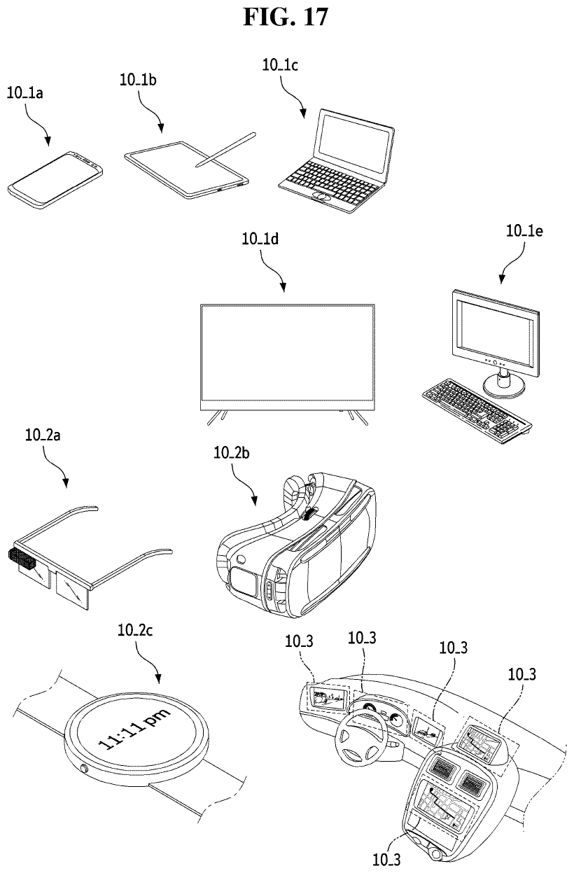

The electronic device 10 (see FIG. 17) according to one embodiment may include the display device 100 described above.

Additionally, the electronic device 10 (see FIG. 17) according to one embodiment may further include a module or device having other additional functions in addition to the display device 100.

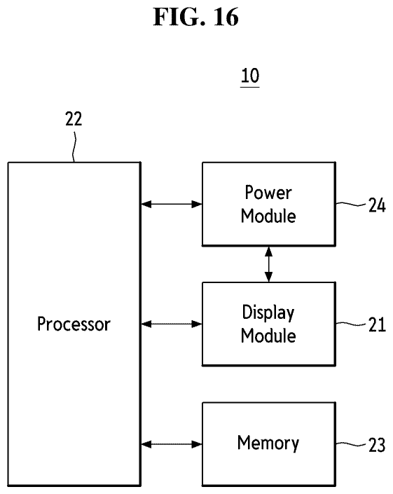

FIG. 16 is a block diagram of an electronic device according to one embodiment.

Referring to FIG. 16, the electronic device 10 according to one embodiment may include a display module 21, a processor 22, a memory 23, and a power module 24.

The display module 21 may include the display device 100 that displays an image.

The processor 22 may include at least one of a central processing unit (CPU), an application processor (AP), a graphic processing unit (GPU), a communication processor (CP), an image signal processor (ISP), or a controller.

The memory 15 may store data information required for the operation of the processor 22 or the display module 21. When the processor 22 executes an application stored in the memory 15, an image data signal and/or an input control signal is transmitted to the display module 21, and the display module 21 may process the received signal and output image information through a display screen.

The power module 24 may include a power supply module, such as a power adapter or a battery device, and a power conversion module that converts the power supplied by the power supply module to generate the power required for the operation of the electronic device 10.

At least one of the components of the electronic device 10 described above may be included in the display device according to the embodiments described above. Further, some of individual modules functionally included in one module may be included in the display device and some others may be provided separately from the display device. For example, the display device 100 may include the display module 21, and the processor 22, the memory 23, and the power module 24 may be provided in the form of other devices in the electronic device 10 other than the display device 100.

FIG. 17 is schematic views of electronic devices according to various embodiments.

Referring to FIG. 17, the electronic devices 10 according to the embodiments may include not only an image display electronic device such as a smartphone 10_1a, a tablet PC 10_1b, a laptop 10_1c, a TV 10_1d, and a desk monitor 10_1e, but also a wearable electronic device such as smart glasses 10_2a, a head mounted display 10_2b, and a smart watch 10_2c, and a vehicle electronic device 10_3 such as a dashboard of a vehicle, a center fascia, a center information display (CID) of the dashboard, and a room mirror display.

However, the effects of the present disclosure are not restricted to the one set forth herein. The above and other effects of the present disclosure will become more apparent to one of daily skill in the art to which the present disclosure pertains by referencing the claims.

What is claimed is:

1. A display device comprising:
a substrate comprising a display area in which emission areas are arranged;
a circuit layer located on the substrate; and
an element layer located on the circuit layer,
wherein the circuit layer comprises:
light emitting pixel drivers arranged side by side with each other in a first direction and a second direction in the display area;
data lines extending in the second direction and transmitting a data signal to the light emitting pixel drivers;
first auxiliary lines extending in the first direction; and
second auxiliary lines extending in the second direction and disposed adjacent to the data lines,
wherein the light emitting pixel drivers comprise a first light emitting pixel driver and a second light emitting pixel driver that are adjacent in the second direction, and
wherein, among the first auxiliary lines, two first auxiliary lines that are adjacent in the second direction intersect the first light emitting pixel driver or the second light emitting pixel driver and are located adjacent to a boundary between the first light emitting pixel driver and the second light emitting pixel driver.

2. The display device of claim 1, wherein the second auxiliary lines comprise one second auxiliary line intersecting the first light emitting pixel driver and the second light emitting pixel driver, and
wherein the one second auxiliary line comprises a first protrusion that overlaps the two first auxiliary lines.

3. The display device of claim 2, wherein the first protrusion further overlaps a second protrusion extending from one first auxiliary line of the two first auxiliary lines.

4. The display device of claim 3, wherein:
the light emitting pixel drivers further comprise a third light emitting pixel driver and a fourth light emitting pixel driver, respectively, adjacent to the first light emitting pixel driver and the second light emitting pixel driver in the first direction,
the two first auxiliary lines intersect the third light emitting pixel driver or the fourth light emitting pixel driver and are located adjacent to a boundary between the third light emitting pixel driver and the fourth light emitting pixel driver,
the second auxiliary lines further comprise another second auxiliary line intersecting the third light emitting pixel driver and the fourth light emitting pixel driver, and
the another second auxiliary line comprises a third protrusion that overlaps the two first auxiliary lines.

5. The display device of claim 4, wherein the third protrusion further overlaps a fourth protrusion extending from another first auxiliary line of the two first auxiliary lines.

6. The display device of claim 5, wherein the second protrusion faces the another first auxiliary line in the second direction, and
wherein the fourth protrusion faces the one first auxiliary line in the second direction.

7. The display device of claim 5, wherein the first protrusion and the third protrusion are arranged with the same width in the second direction and are arranged side by side in the first direction.

8. The display device of claim 7, further comprising a display driving circuit supplying a data signal to the data lines,
wherein:
the substrate further comprises a non-display area located around the display area,
the circuit layer further comprises data supply lines located in the non-display area and electrically connected between the data lines and the display driving circuit,
a bypass area on one side of the display area comprises a bypass middle area, a first bypass side area that extends parallel to the bypass middle area in the first direction and in contact with the non-display area, and a second bypass side area that is located between the bypass middle area and the first bypass side area,
the data supply lines extend to the bypass middle area and the second bypass side area,
the data lines comprise a first data line located in the first bypass side area and a second data line located in the second bypass side area,
the first auxiliary lines comprise a first bypass auxiliary line electrically connected to the first data line,
the second auxiliary lines comprise a second bypass auxiliary line that is electrically connected to the first bypass auxiliary line and is adjacent to the second data line,
among the data supply lines, a first data supply line transmitting a data signal of the first data line is electrically connected to the first data line through the first bypass auxiliary line and the second bypass auxiliary line, and
among the data supply lines, a second data supply line transmitting a data signal of the second data line is electrically connected directly to the second data line.

9. The display device of claim 7, wherein the element layer comprises light emitting elements arranged in the emission areas, each of the light emitting pixel drivers comprises:
a first transistor generating the driving current;
a second transistor electrically connected between one of the data lines and a gate electrode of the first transistor;
a third transistor electrically connected between a reference voltage line transmitting a reference voltage and the gate electrode of the first transistor;
a fourth transistor electrically connected between an initialization voltage line transmitting an initialization voltage and one of the light emitting elements;
a fifth transistor electrically connected between a first power line transmitting a first power and a first electrode portion of the first transistor;
a sixth transistor electrically connected between the one light emitting element and a second electrode portion of the first transistor;
a first capacitor electrically connected between the gate electrode of the first transistor and the second electrode portion of the first transistor; and
a second capacitor electrically connected between the first power line transmitting the first power and the second electrode portion of the first transistor,
wherein:
a gate electrode of the second transistor is electrically connected to a scan write line transmitting a scan write signal,
a gate electrode of the third transistor is electrically connected to a reset control line transmitting a reset control signal,
a gate electrode of the fourth transistor is electrically connected to an initialization control line transmitting an initialization control signal,
a gate electrode of the fifth transistor is electrically connected to a first emission control line transmitting a first emission control signal, and
a gate electrode of the sixth transistor is electrically connected to a second emission control line transmitting a second emission control signal.

10. The display device of claim 9, wherein the circuit layer comprises:
a first semiconductor layer located on the substrate;
a first interlayer insulating layer located on the first semiconductor layer; and
a second semiconductor layer located on the first interlayer insulating layer and containing an oxide semiconductor material,
wherein a channel portion, the first electrode portion and the second electrode portion of the first transistor are located in the second semiconductor layer, and
wherein a channel portion, a first electrode portion and a second electrode portion of the sixth transistor are located in the first semiconductor layer.

11. The display device of claim 9, wherein the light emitting pixel drivers further comprise a fifth light emitting pixel driver adjacent to the second light emitting pixel driver in the second direction,
wherein each of the reference voltage line, the reset control line, the first emission control line, the second emission control line, the initialization control line, and the initialization voltage line extends in the first direction, and
wherein some of the reference voltage line, the reset control line, the first emission control line, the second emission control line, the initialization control line, and the initialization voltage line intersect the second light emitting pixel driver, and some others intersect the fifth light emitting pixel driver.

12. The display device of claim 11, wherein the third transistor of each of the second light emitting pixel driver and the fifth light emitting pixel driver is electrically connected to the reset control line and the reference voltage line intersecting the second light emitting pixel driver,
wherein the fourth transistor of each of the second light emitting pixel driver and the fifth light emitting pixel driver is electrically connected to the initialization voltage line and the initialization control line intersecting the fifth light emitting pixel driver,
wherein the fifth transistor of each of the second light emitting pixel driver and the fifth light emitting pixel driver is electrically connected to the first emission control line intersecting the second light emitting pixel driver, and
wherein the sixth transistor of each of the second light emitting pixel driver and the fifth light emitting pixel driver is electrically connected to the second emission control line intersecting the fifth light emitting pixel driver.

13. The display device of claim 12, wherein the third transistor and the fifth transistor of the fifth light emitting pixel driver are respectively adjacent to the third transistor and the fifth transistor of the second light emitting pixel driver in the first direction, and
wherein the fourth transistor and the sixth transistor of the second light emitting pixel driver are respectively adjacent to the fourth transistor and the sixth transistor of the fifth light emitting pixel driver in the first direction.

14. An electronic device comprising:
a display device displaying an image;
a memory storing an application;
a processor executing the application and transmitting an image data signal and an input control signal to the display device; and
a power module transmitting power to the display device,
wherein the display device comprises:
a substrate comprising a display area in which emission areas are arranged;
a circuit layer located on the substrate; and
an element layer located on the circuit layer,
wherein the circuit layer comprises:
light emitting pixel drivers arranged side by side with each other in a first direction and a second direction in the display area;
data lines extending in the second direction and transmitting a data signal to the light emitting pixel drivers;
first auxiliary lines extending in the first direction; and
second auxiliary lines extending in the second direction and disposed adjacent to the data lines,
wherein the light emitting pixel drivers comprise:
a first light emitting pixel driver and a second light emitting pixel driver that are adjacent to each other in the second direction; and
a third light emitting pixel driver and a fourth light emitting pixel driver, respectively, adjacent to the first light emitting pixel driver and the second light emitting pixel driver in the first direction,
wherein, among the first auxiliary lines, two first auxiliary lines that are adjacent in the second direction intersect the first light emitting pixel driver or the second light emitting pixel driver and are located adjacent to a boundary between the first light emitting pixel driver and the second light emitting pixel driver, and
wherein the two first auxiliary lines intersect the third light emitting pixel driver or the fourth light emitting pixel driver and are located adjacent to a boundary between the third light emitting pixel driver and the fourth light emitting pixel driver.

15. The electronic device of claim 14, wherein the second auxiliary lines comprise:
one second auxiliary line intersecting the first light emitting pixel driver and the second light emitting pixel driver; and
another second auxiliary line intersecting the third light emitting pixel driver and the fourth light emitting pixel driver,
wherein:
the one second auxiliary line comprises a first protrusion overlapping the two first auxiliary lines,
the first protrusion further overlaps a second protrusion extending from one first auxiliary line of the two first auxiliary lines,
the another second auxiliary line comprises a third protrusion overlapping the two first auxiliary lines, and
the third protrusion further overlaps a fourth protrusion extending from the other first auxiliary line of the two first auxiliary lines.

16. The electronic device of claim 15, wherein:
the second protrusion faces another first auxiliary line of the two first auxiliary lines in the second direction,
the fourth protrusion faces the one first auxiliary line in the second direction, and
the first protrusion and the third protrusion are arranged with the same width in the second direction and are arranged side by side in the first direction.

17. The electronic device of claim 16, wherein:
the display device further comprises a display driving circuit supplying a data signal to the data lines,
the substrate further comprises a non-display area located around the display area,
the circuit layer further comprises data supply lines located in the non-display area and electrically connected between the data lines and the display driving circuit,
wherein a bypass area on one side of the display area comprises a bypass middle area, a first bypass side area that extends parallel to the bypass middle area in the first direction and in contact with the non-display area, and a second bypass side area that is located between the bypass middle area and the first bypass side area, and
wherein:
the data supply lines extend to the bypass middle area and the second bypass side area,
the data lines comprise a first data line located in the first bypass side area, and a second data line located in the second bypass side area,
the first auxiliary lines comprise a first bypass auxiliary line electrically connected to the first data line,
the second auxiliary lines comprise a second bypass auxiliary line that is electrically connected to the first bypass auxiliary line and is adjacent to the second data line,
among the data supply lines, a first data supply line transmitting a data signal of the first data line is electrically connected to the first data line through the first bypass auxiliary line and the second bypass auxiliary line, and
among the data supply lines, a second data supply line transmitting a data signal of the second data line is electrically connected directly to the second data line.

18. The electronic device of claim 16, wherein the element layer comprises light emitting elements arranged in the emission areas,
each of the light emitting pixel drivers comprises:
a first transistor generating the driving current;
a second transistor electrically connected between one of the data lines and a gate electrode of the first transistor;
a third transistor electrically connected between a reference voltage line transmitting a reference voltage and the gate electrode of the first transistor;
a fourth transistor electrically connected between an initialization voltage line transmitting an initialization voltage and one of the light emitting elements;
a fifth transistor electrically connected between a first power line transmitting a first power and a first electrode portion of the first transistor;
a sixth transistor electrically connected between the one light emitting element and a second electrode portion of the first transistor;
a first capacitor electrically connected between the gate electrode of the first transistor and the second electrode portion of the first transistor; and
a second capacitor electrically connected between the first power line transmitting the first power and the second electrode portion of the first transistor,
wherein a gate electrode of the second transistor is electrically connected to a scan write line transmitting a scan write signal,
a gate electrode of the third transistor is electrically connected to a reset control line transmitting a reset control signal,
a gate electrode of the fourth transistor is electrically connected to an initialization control line transmitting an initialization control signal,
a gate electrode of the fifth transistor is electrically connected to a first emission control line transmitting a first emission control signal, and
a gate electrode of the sixth transistor is electrically connected to a second emission control line transmitting a second emission control signal,
the light emitting pixel drivers further comprise a fifth light emitting pixel driver adjacent to the second light emitting pixel driver in the second direction,
each of the reference voltage line, the reset control line, the first emission control line, the second emission control line, the initialization control line, and the initialization voltage line extends in the first direction,
some of the reference voltage line, the reset control line, the first emission control line, the second emission control line, the initialization control line, and the initialization voltage line intersect the second light emitting pixel driver, and some others intersect the fifth light emitting pixel driver.

19. The electronic device of claim 18, wherein the third transistor and the fifth transistor of the fifth light emitting pixel driver are respectively adjacent to the third transistor and the fifth transistor of the second light emitting pixel driver in the first direction, and
wherein the fourth transistor and the sixth transistor of the second light emitting pixel driver are respectively adjacent to the fourth transistor and the sixth transistor of the fifth light emitting pixel driver in the first direction.

20. The electronic device of claim 18, wherein the circuit layer comprises:
a first semiconductor layer located on the substrate;
a first interlayer insulating layer located on the first semiconductor layer; and
a second semiconductor layer located on the first interlayer insulating layer and containing an oxide semiconductor material,
wherein:
each of the first transistor, the second transistor, the third transistor, the fourth transistor, the fifth transistor, and the sixth transistor comprises a gate electrode, a channel portion overlapping the gate electrode, a first electrode portion connected to one side of the channel portion, and a second electrode portion connected to the other side of the channel portion,
the channel portion, the first electrode portion and the second electrode portion of each of the first transistor, the second transistor, the third transistor and the fourth transistor are located in the second semiconductor layer, and
the channel portion, the first electrode portion and the second electrode portion of each of the fifth transistor and the sixth transistor are located in the first semiconductor layer.
